(19) United States
(12) Patent Application Publication
(10) Pub. No.: US 2026/0244799 A1
(43) Pub. Date: Aug. 20, 2026

(54) METROLOGY METHOD AND ASSOCIATED METROLOGY DEVICE

(71) Applicant: ASML Netherlands B.V., Veldhoven (NL)

(72) Inventors: Omar EL GAWHARY, Veldhoven (NL); Patrick Philipp HELFENSTEIN, Eindhoven (NL); Loes Frederique VAN RIJSWIJK, Eindhoven (NL); Niels GEYPEN, Lommel (BE); Hugo Laurent JONQUIERE, Eindhoven (NL); Andrea INVERNIZZI, Eindhoven (NL); Hugo Augustinus Joseph CRAMER, Eindhoven (NL)

(73) Assignee: ASML Netherlands B.V., Veldhoven (NL)

(21) Appl. No.: 18/874,476

(22) PCT Filed: Aug. 2, 2023
(86) PCT No.: PCT/EP2023/071435

§ 371 Date: Dec. 12, 2024

(30) Foreign Application Priority Data
Sep. 7, 2022 (EP) 22194304.6
Oct. 25, 2022 (EP) 22203557.8

(51) Int. Cl. G06F 30/13

(52) U.S. Cl. CPC G06F 30/13

(57) ABSTRACT

Disclosed is a method of determining at least one parameter of interest relating to a structure formed in at least one respective layer on a substrate, the method comprising: obtaining a measured metrology data relating to a measurement of the structure; obtaining a model, the model describing the structure in terms of a plurality of model parameters, the model parameters comprising estimated values; and performing in sequence a plurality of optimization steps, based on the measured metrology data, to determine the plurality of model parameters, each of the plurality of optimization steps determining a subset of the plurality of model parameters.

### CROSS REFERENCE TO RELATED APPLICATIONS

This application claims priority of EP application 22194304.6 which was filed on 2022 Sep. 7 and of EP application 22203557.8 which was filed on 2022 Oct. 25 and whom are incorporated herein in their entirety by reference.

### FIELD

The present invention relates to a metrology method and device which may, for example, be used for determining a characteristic of structures on a substrate.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k₁.

In lithographic processes, as well as other manufacturing processes, it is desirable frequently to make measurements of the structures created, e.g., for process control and verification. Various tools for making such measurements are known, including scanning electron microscopes, which are often used to measure critical dimension (CD), and specialized tools to measure overlay, the accuracy of alignment of two layers in a device. Recently, various forms of scatterometers have been developed for use in the lithographic field.

The manufacturing processes may be for example lithography, etching, deposition, chemical mechanical planarization, oxidation, ion implantation, diffusion or a combination of two or more of them.

Examples of known scatterometers often rely on provision of dedicated metrology targets. For example, a method may require a target in the form of a simple grating that is large enough that a measurement beam generates a spot that is smaller than the grating (i.e., the grating is underfilled). In so-called reconstruction methods, properties of the grating can be calculated by simulating interaction of scattered radiation with a mathematical model of the target structure. Parameters of the model are adjusted until the simulated interaction produces a diffraction pattern similar to that observed from the real target.

In addition to measurement of feature shapes by reconstruction, diffraction-based overlay can be measured using such apparatus, as described in published patent application US2006066855A1. Diffraction-based overlay metrology using dark-field imaging of the diffraction orders enables overlay measurements on smaller targets. These targets can be smaller than the illumination spot and may be surrounded by product structures on a wafer. Examples of dark field imaging metrology can be found in numerous published patent applications, such as for example US2011102753A1 and US20120044470A. Multiple gratings can be measured in one image, using a composite grating target. The known scatterometers tend to use light in the visible or near-infrared (IR) wave range, which requires the pitch of the grating to be much coarser than the actual product structures whose properties are actually of interest. Such product features may be defined using deep ultraviolet (DUV), extreme ultraviolet (EUV) or X-ray radiation having far shorter wavelengths. Unfortunately, such wavelengths are not normally available or usable for metrology.

On the other hand, the dimensions of modern product structures are so small that they cannot be imaged by optical metrology techniques. Small features include for example those formed by multiple patterning processes, and/or pitch-multiplication. Hence, targets used for high-volume metrology often use features that are much larger than the products whose overlay errors or critical dimensions are the property of interest. The measurement results are only indirectly related to the dimensions of the real product structures, and may be inaccurate because the metrology target does not suffer the same distortions under optical projection in the lithographic apparatus, and/or different processing in other steps of the manufacturing process. While scanning electron microscopy (SEM) is able to resolve these modern product structures directly, SEM is much more time consuming than optical measurements. Moreover, electrons are not able to penetrate through thick process layers, which makes them less suitable for metrology applications. Other techniques, such as measuring electrical properties using contact pads is also known, but it provides only indirect evidence of the true product structure.

By decreasing the wavelength of the radiation used during metrology it is possible to resolve smaller structures, to increase sensitivity to structural variations of the structures and/or penetrate further into the product structures. One such method of generating suitably high frequency radiation (e.g. hard X-ray, soft X-ray and/or EUV radiation) may be using a pump radiation (e.g., infrared IR radiation) to excite a generating medium, thereby generating an emitted radiation, optionally a high harmonic generation comprising high frequency radiation.

Present reconstruction techniques, to reconstruct parameters of a structure being measured, are mathematically and computationally complex due to the number of permutations of parameters to be varied. It often also requires prior knowledge with accurate many-parameters describing the measured sample, while the detailed sample information may not be available. To address this, at least in the context of overlay metrology, other overlay measurement techniques have been developed which do not require reconstruction, e.g., those based on measurements of asymmetry of targets, which are typically biased to separate the overlay asymmetry from other asymmetries.

It would be desirable to improve on such reconstruction techniques and/or overlay metrology techniques.

### SUMMARY

In a first aspect of the invention, there is provided a method of determining at least one parameter of interest relating to a structure formed in at least one respective layer on a substrate, the method comprising: obtaining a measured metrology data relating to a measurement of the structure; obtaining a model, the model describing the structure in terms of a plurality of model parameters, the model parameters comprising estimated values; and performing in sequence a plurality of optimization steps, based on the measured metrology data, to determine the plurality of model parameters, each of the plurality of optimization steps determining a subset of the plurality of model parameters.

According to a second aspect of the present invention there is provided a computer program product containing one or more sequences of machine-readable instructions for implementing calculating steps in a method according to the first aspect of the invention as set forth above.

The invention yet further provides a processing arrangement and metrology device comprising the computer program of the second aspect.

These and other aspects and advantages of the apparatus and methods disclosed herein will be appreciated from a consideration of the following description and drawings of exemplary embodiments.

### BRIEF DESCRIPTION OF THE DRAWINGS

Embodiments will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 schematically illustrates a scatterometry apparatus;

FIG. 5 schematically illustrates a transmissive scatterometry apparatus;

FIG. 6 depicts a schematic representation of a metrology apparatus in which EUV and/or SXR radiation is used;

FIG. 7 depicts a simplified schematic drawing of an illumination source;

FIG. 8 illustrates (a) a portion of an overlay target showing true dimensions; and (b) a model of the same overlay target comprising estimated dimensions, as used in an initial setup of a method of an embodiment;

FIG. 9 illustrates (a) the portion of an overlay target showing true dimensions as illustrated in FIG. 8(a); and (b) a model of the same overlay target comprising some estimated dimensions, and dimensions optimized in the first step using the method of an embodiment;

FIG. 10 illustrates (a) the portion of an overlay target showing true dimensions as illustrated in FIG. 8(a); and (b) a model of the same overlay target following performance of the method of an embodiment for determining overlay;

FIG. 11 illustrates a portion of a target structure on a stack illustrating the parameters which can be reconstructed using methods according to a further embodiment;

FIGS. 12(a) and 12(b) is a flowchart describing a method for determining an optimization sequence in accordance with an embodiment;

FIG. 13(a) is a chart describing the diagonal of a covariance matrix for a plurality of example parameters relating to a structure as determined in the method of FIG. 12;

FIG. 13(b) is a chart describing a correlation matrix for the plurality of example parameters relating to a structure as determined in the method of FIG. 12; and

FIG. 13(c) is a flow diagram illustrating an exemplary optimization sequence determined using the method of FIG. 12.

### DETAILED DESCRIPTION

In the present document, the terms “radiation” and “beam” are used to encompass all types of electromagnetic radiation and particle radiation, including ultraviolet radiation (e.g. with a wavelength of 365, 248, 193, 157 or 126 nm), EUV (extreme ultra-violet radiation, e.g. having a wavelength in the range of about 5-100 nm), X-ray radiation, electron beam radiation and other particle radiation.

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

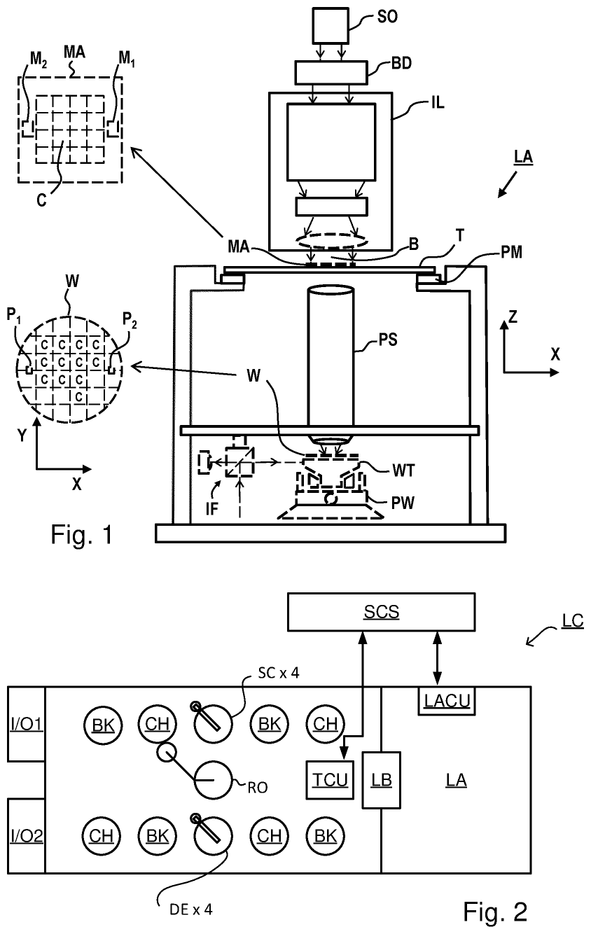

FIG. 1 schematically depicts a lithographic apparatus LA. The lithographic apparatus LA includes an illumination system (also referred to as illuminator) IL configured to condition a radiation beam B (e.g., UV radiation, DUV radiation, EUV radiation or X-ray radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, diffractive, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, diffractive, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference in its entirety.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support T, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT may be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, may be under the control of a track control unit TCU that in itself may be controlled by a supervisory control system SCS, which may also control the lithographic apparatus LA, e.g. via lithography control unit LACU.

In lithographic processes, it is desirable to make frequently measurements of the structures created, e.g., for process control and verification. Tools to make such measurement may be called metrology tools MT. Different types of metrology tools MT for making such measurements are known, including scanning electron microscopes or various forms of scatterometer metrology tools MT. Scatterometers are versatile instruments which allow measurements of the parameters of a lithographic process by having a sensor in or close to the pupil or a conjugate plane with the pupil of the objective of the scatterometer, measurements usually referred as pupil based measurements, or by having the sensor in or close to an image plane or a plane conjugate with the image plane, in which case the measurements are usually referred as image or field based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure gratings using light from hard X-ray (HXR), soft X-ray (SXR), extreme ultraviolet (EUV), visible to near-infrared (IR) and IR wavelength range. In case that the radiation is hard X-ray or soft X-ray, the aforementioned scatterometers may optionally be a small-angle X-ray scattering metrology tool.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), shape of structures, etc. For this purpose, inspection tools and/or metrology tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

In a first embodiment, the scatterometer MT is an angular resolved scatterometer. In such a scatterometer reconstruction methods may be applied to the measured signal to reconstruct or calculate properties of the grating. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In a second embodiment, the scatterometer MT is a spectroscopic scatterometer MT. In such spectroscopic scatterometer MT, the radiation emitted by a radiation source is directed onto the target and the reflected, transmitted or scattered radiation from the target is directed to a spectrometer detector, which measures a spectrum (i.e. a measurement of intensity as a function of wavelength) of the specular reflected radiation. From this data, the structure or profile of the target giving rise to the detected spectrum may be reconstructed, e.g. by Rigorous Coupled Wave Analysis and non-linear regression or by comparison with a library of simulated spectra.

In a third embodiment, the scatterometer MT is an ellipsometric scatterometer. The ellipsometric scatterometer allows for determining parameters of a lithographic process by measuring scattered or transmitted radiation for each polarization states. Such metrology apparatus emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

In one embodiment of the scatterometer MT, the scatterometer MT is adapted to measure the overlay of two misaligned gratings or periodic structures by measuring asymmetry in the reflected spectrum and/or the detection configuration, the asymmetry being related to the extent of the overlay. The two (maybe overlapping) grating structures may be applied in two different layers (not necessarily consecutive layers), and may be formed substantially at the same position on the wafer. The scatterometer may have a symmetrical detection configuration as described e.g. in co-owned patent application EP1,628,164A, such that any asymmetry is clearly distinguishable. This provides a straightforward way to measure misalignment in gratings. Further examples for overlay error between the two layers containing periodic structures as target is measured through asymmetry of the periodic structures may be found in PCT patent application publication no. WO 2011/012624 or US patent application US 20160161863, incorporated herein by reference in its entirety.

Other parameters of interest may be focus and dose. Focus and dose may be determined simultaneously by scatterometry (or alternatively by scanning electron microscopy) as described in US patent application US2011-0249244, incorporated herein by reference in its entirety. A single structure may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings, formed by a lithographic process, mostly in resist, but also after other manufacturing process, etch process for example. The pitch and line-width of the structures in the gratings may strongly depend on the measurement optics (in particular the NA of the optics) to be able to capture diffraction orders coming from the metrology targets. As indicated earlier, the diffracted signal may be used to determine shifts between two layers (also referred to ‘overlay’) or may be used to reconstruct at least part of the original grating as produced by the lithographic process. This reconstruction may be used to provide guidance of the quality of the lithographic process and may be used to control at least part of the lithographic process. Targets may have smaller sub-segmentation which are configured to mimic dimensions of the functional part of the design layout in a target. Due to this sub-segmentation, the targets will behave more similar to the functional part of the design layout such that the overall process parameter measurements resemble the functional part of the design layout better. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

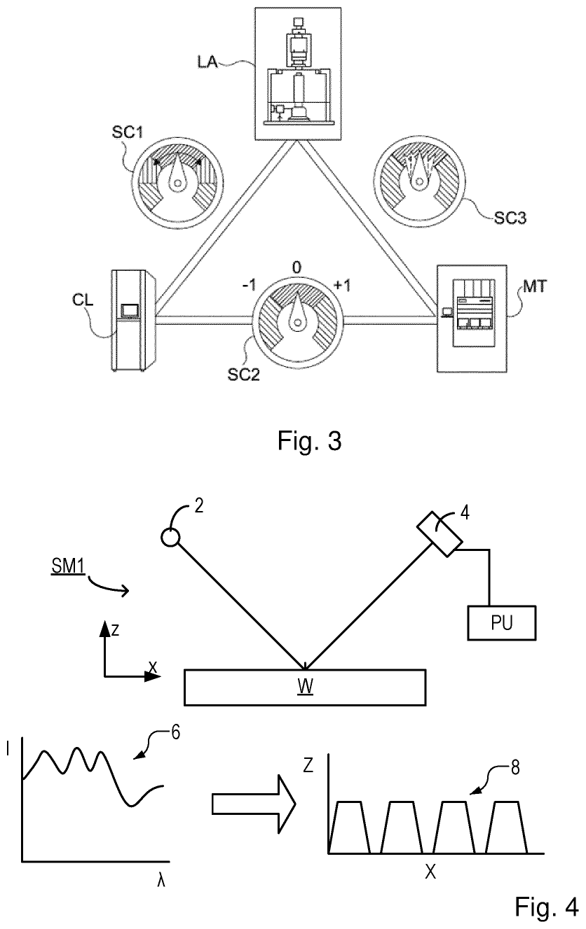

The patterning process in a lithographic apparatus LA may be one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—maybe within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). The resolution enhancement techniques may be arranged to match the patterning possibilities of the lithographic apparatus LA. The computer system CL may also be used to detect where within the process window the lithographic apparatus LA is currently operating (e.g. using input from the metrology tool MET) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

Many different forms of metrology tools MT for measuring structures created using lithographic pattering apparatus can be provided. Metrology tools MT may use electromagnetic radiation to interrogate a structure. Properties of the radiation (e.g. wavelength, bandwidth, power) can affect different measurement characteristics of the tool, with shorter wavelengths generally allowing for increased resolution. Radiation wavelength has an effect on the resolution the metrology tool can achieve. Therefore, in order to be able to measure structures with features having small dimensions, metrology tools MT with short wavelength radiation sources are preferred.

Another way in which radiation wavelength can affect measurement characteristics is penetration depth, and the transparency/opacity of materials to be inspected at the radiation wavelength. Depending on the opacity and/or penetration depth, radiation can be used for measurements in transmission or reflection. The type of measurement can affect whether information is obtained about the surface and/or the bulk interior of a structure/substrate. Therefore, penetration depth and opacity are another element to be taken into account when selecting radiation wavelength for a metrology tool.

In order to achieve higher resolution for measurement of lithographically patterned structures, metrology tools MT with short wavelengths are preferred. This may include wavelengths shorter than visible wavelengths, for example in the UV, EUV, and X-ray portions of the electromagnetic spectrum. Hard X-ray methods such as Transmitted Small Angle X-ray Scattering (TSAXS) make use of the high resolution and high penetration depth of hard X-rays and may therefore operate in transmission. Soft X-rays and EUV, on the other hand, do not penetrate the target as far but may induce a rich optical response in the material to be probed. This may be due the optical properties of many semiconductor materials, and due to the structures being comparable in size to the probing wavelength. As a result, EUV and/or soft X-ray metrology tools MT may operate in reflection, for example by imaging, or by analyzing diffraction patterns from, a lithographically patterned structure.

For hard X-ray, soft X-ray and EUV radiations, applications in high volume manufacturing (HVM) applications may be limited due to a lack of available high-brilliance radiation sources at the required wavelengths. In the case of hard X-rays, commonly used sources in industrial applications include X-ray tubes. X-ray tubes, including advanced X-ray tubes for example based on liquid metal anodes or rotating anodes, may be relatively affordable and compact, but may lack brilliance required for HVM applications. High brilliance X-ray sources such as Synchrotron Light Sources (SLSs) and X-ray Free Electron Lasers (XFELs) currently exist, but their size (>100 m) and high cost (multi-100-million euro), makes them prohibitively large and expensive for metrology applications. Similarly, there is a lack of availability of sufficiently bright EUV and soft X-ray radiation sources.

One example of a metrology apparatus, such as a scatterometer, is depicted in FIG. 4. It may comprise a broadband (e.g. white light) radiation projector 2 which projects radiation 5 onto a substrate W. The reflected or scattered radiation 10 is passed to a spectrometer detector 4, which measures a spectrum 6 (i.e. a measurement of intensity I as a function of wavelength λ) of the specular reflected radiation. From this data, the structure or profile 8 giving rise to the detected spectrum may be reconstructed by processing unit PU, e.g. by Rigorous Coupled Wave Analysis and non-linear regression or by comparison with a library of simulated spectra as shown at the bottom of FIG. 4. In general, for the reconstruction, the general form of the structure is known, and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer.

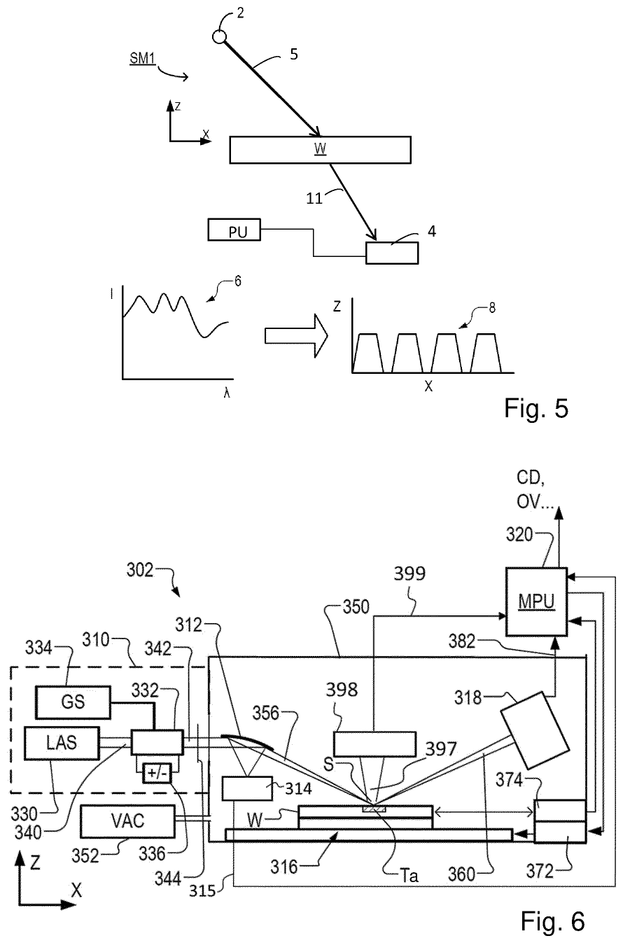

A transmissive version of the example of a metrology apparatus, such as a scatterometer shown in FIG. 4, is depicted in FIG. 5. The transmitted radiation 11 is passed to a spectrometer detector 4, which measures a spectrum 6 as discussed for FIG. 4. Such a scatterometer may be configured as a normal-incidence scatterometer or an oblique-incidence scatterometer. Optionally, the transmissive version using hard X-ray radiation with wavelength <1 nm, optionally <0.1 nm, optionally <0.01 nm.

As an alternative to optical metrology methods, it has also been considered to use hard X-ray, soft X-rays or EUV radiation, for example radiation with at least one of the wavelength ranges: <0.01 nm, <0.1 nm, <1 nm, between 0.01 nm and 100 nm, between 0.01 nm and 50 nm, between 1 nm and 50 nm, between 1 nm and 20 nm, between 5 nm and 20 nm, and between 10 nm and 20 nm. One example of metrology tool functioning in one of the above presented wavelength ranges is transmissive small angle X-ray scattering (T-SAXS as in US 2007224518A which content is incorporated herein by reference in its entirety). Profile (CD) measurements using T-SAXS are discussed by Lemaillet et al in “Intercomparison between optical and X-ray scatterometry measurements of FinFET structures”, Proc. of SPIE, 2013, 8681. It is noted that the use of laser produced plasma (LPP) x-ray source is described in U.S. Patent Publication No. 2019/003988A1, and in U.S. Patent Publication No. 2019/215940A1, which are incorporated herein by reference in the entirety. Reflectometry techniques using X-rays (GI-XRS) and extreme ultraviolet (EUV) radiation at grazing incidence may be used for measuring properties of films and stacks of layers on a substrate. Within the general field of reflectometry, goniometric and/or spectroscopic techniques may be applied. In goniometry, the variation of a reflected beam with different incidence angles may be measured. Spectroscopic reflectometry, on the other hand, measures the spectrum of wavelengths reflected at a given angle (using broadband radiation). For example, EUV reflectometry has been used for inspection of mask blanks, prior to manufacture of reticles (patterning devices) for use in EUV lithography.

It is possible that the range of application makes the use of wavelengths in e.g. the hard-X-rays, soft X-rays or EUV domain not sufficient. Published patent applications US 20130304424A1 and US2014019097A1 (Bakeman et al/KLA) describe hybrid metrology techniques in which measurements made using x-rays and optical measurements with wavelengths in the range 120 nm and 2000 nm are combined together to obtain a measurement of a parameter such as CD. A CD measurement is obtained by coupling and x-ray mathematical model and an optical mathematical model through one or more common. The contents of the cited US patent applications are incorporated herein by reference in their entirety.

FIG. 6 depicts a schematic representation of a metrology apparatus 302 in which the aforementioned radiation may be used to measure parameters of structures on a substrate. The metrology apparatus 302 presented in FIG. 6 may be suitable for the hard X-ray, soft X-rays and/or EUV domain.

FIG. 6 illustrates a schematic physical arrangement of a metrology apparatus 302 comprising a spectroscopic scatterometer using hard X-ray, Soft X-Ray and/or EUV radiation optionally in grazing incidence, purely by way of example. An alternative form of inspection apparatus might be provided in the form of an angle-resolved scatterometer, which may use radiation in normal or near-normal incidence similar to the conventional scatterometers operating at longer wavelengths, and which may also use radiation with direction being greater than 1° or 2° from a direction parallel to the substrate. An alternative form of inspection apparatus might be provided in the form of a transmissive scatterometer, to which the configuration in FIG. 5 applies.

Inspection apparatus 302 comprises a radiation source or called illumination source 310, illumination system 312, substrate support 316, detection systems 318, 398 and metrology processing unit (MPU) 320.

An illumination source 310 in this example is for a generation of EUV, hard X-ray or soft X-ray radiation. The illumination source 310 may be based on high harmonic generation (HHG) techniques as shown in FIG. 6, and it may also be other types of illumination sources, e.g. liquid metal jet source, inverse Compton scattering (ICS) source, plasma channel source, magnetic undulator source, free electron laser (FEL) source, compact storage ring source, electrical discharge produced plasma source, soft X-ray laser source, rotating anode source, solid anode source, particle accelerator source, microfocus source, or laser produced plasma source.

The HHG source may be a gas jet/nozzle source, a capillary/fiber source or a gas cell source.

For the example of HHG source, as shown in FIG. 6, main components of the radiation source are a pump radiation source 330 operable to emit the pump radiation and a gas delivery system 332. Optionally the pump radiation source 330 is a laser, optionally the pump radiation source 330 is a pulsed high-power infrared or optical laser. The pump radiation source 330 may be, for example, a fiber-based laser with an optical amplifier, producing pulses of infrared radiation that may last for example less than 1 ns (1 nanosecond) per pulse, with a pulse repetition rate up to several megahertz, as required. The wavelength of the infrared radiation may be in the range 200 nm to 10 μm, for example in the region of 1 μm (1 micron). Optionally, the laser pulses are delivered as a first pump radiation 340 to the gas delivery system 332, wherein the gas a portion of the radiation is converted to higher frequencies than the first radiation into an emitted radiation 342. A gas supply 334 supplies a suitable gas to the gas delivery system 332, where it is optionally ionized by an electric source 336. The gas delivery system 332 may be a cut tube.

A gas provided by the gas delivery system 332 defines a gas target, which may be a gas flow or a static volume. The gas may be for example air, Neon (Ne), Helium (He), Nitrogen (N₂), Oxygen (O₂), Argon (Ar), Krypton (Kr), Xenon (Xe), Carbon dioxide and the combination of them. These may be selectable options within the same apparatus. The emitted radiation may contain multiple wavelengths. If the emitted radiation were monochromatic, then measurement calculations (for example reconstruction) may be simplified, but it is easier to produce radiation with several wavelengths. An emission divergence angle of the emitted radiation may be wavelength dependent. Different wavelengths may, for example, provide different levels of contrast when imaging structure of different materials. For inspection of metal structures or silicon structures, for example, different wavelengths may be selected to those used for imaging features of (carbon-based) resist, or for detecting contamination of such different materials. One or more filtering devices 344 may be provided. For example a filter such as a thin membrane of Aluminum (Al) or Zirconium (Zr) may serve to cut the fundamental IR radiation from passing further into the inspection apparatus. A grating (not shown) may be provided to select one or more specific wavelengths from among those generated. Optionally the illumination source comprises a space that is configured to be evacuated and the gas delivery system is configured to provide a gas target in the space. Optionally some or all of the beam paths may be contained within a vacuum environment, bearing in mind that SXR and/or EUV radiation is absorbed when traveling in air. The various components of radiation source 310 and illumination optics 312 may be adjustable to implement different metrology ‘recipes’ within the same apparatus. For example different wavelengths and/or polarization may be made selectable.

Depending on the materials of the structure under inspection, different wavelengths may offer a desired level of penetration into lower layers. For resolving the smallest device features and defects among the smallest device features, then a short wavelength is likely to be preferred. For example, one or more wavelengths in the range 0.01-20 nm or optionally in the range 1-10 nm or optionally in the range 10-20 nm may be chosen. Wavelengths shorter than 5 nm may suffer from very low critical angle when reflecting off materials of interest in semiconductor manufacture. Therefore to choose a wavelength greater than 5 nm may provide stronger signals at higher angles of incidence. On the other hand, if the inspection task is for detecting the presence of a certain material, for example to detect contamination, then wavelengths up to 50 nm could be useful.

From the radiation source 310, the filtered beam 342 may enter an inspection chamber 350 where the substrate W including a structure of interest is held for inspection at a measurement position by substrate support 316. The structure of interest is labeled T. Optionally the atmosphere within inspection chamber 350 may be maintained near vacuum by vacuum pump 352, so that SXR and/or EUV radiation may pass with-out undue attenuation through the atmosphere. The Illumination system 312 has the function of focusing the radiation into a focused beam 356, and may comprise for example a two-dimensionally curved mirror, or a series of one-dimensionally curved mirrors, as described in published US patent application US2017/0184981A1 (which content is incorporated herein by reference in its entirety), mentioned above. The focusing is performed to achieve a round or elliptical spot S under 10 μm in diameter, when projected onto the structure of interest. Substrate support 316 comprises for example an X-Y translation stage and a rotation stage, by which any part of the substrate W may be brought to the focal point of beam to in a desired orientation. Thus the radiation spot S is formed on the structure of interest. Alternatively, or additionally, substrate support 316 comprises for example a tilting stage that may tilt the substrate W at a certain angle to control the angle of incidence of the focused beam on the structure of interest T.

Optionally, the illumination system 312 provides a reference beam of radiation to a reference detector 314 which may be configured to measure a spectrum and/or intensities of different wavelengths in the filtered beam 342. The reference detector 314 may be configured to generate a signal 315 that is provided to processor 320 and the filter may comprise information about the spectrum of the filtered beam 342 and/or the intensities of the different wavelengths in the filtered beam.

Reflected radiation 360 is captured by detector 318 and a spectrum is provided to processor 320 for use in calculating a property of the target structure T. The illumination system 312 and detection system 318 thus form an inspection apparatus. This inspection apparatus may comprise a hard X-ray, soft X-ray and/or EUV spectroscopic reflectometer of the kind described in US2016282282A1 which content is incorporated herein by reference in its entirety.

If the target Ta has a certain periodicity, the radiation of the focused beam 356 may be partially diffracted as well. The diffracted radiation 397 follows another path at well-defined angles with respect to the angle of incidence then the reflected radiation 360. In FIG. 6, the drawn diffracted radiation 397 is drawn in a schematic manner and diffracted radiation 397 may follow many other paths than the drawn paths. The inspection apparatus 302 may also comprise further detection systems 398 that detect and/or image at least a portion of the diffracted radiation 397. In FIG. 6 a single further detection system 398 is drawn, but embodiments of the inspection apparatus 302 may also comprise more than one further detection system 398 that are arranged at different position to detect and/or image diffracted radiation 397 at a plurality of diffraction directions. In other words, the (higher) diffraction orders of the focused radiation beam that impinges on the target Ta are detected and/or imaged by one or more further detection systems 398. The one or more detection systems 398 generates a signal 399 that is provided to the metrology processor 320. The signal 399 may include information of the diffracted light 397 and/or may include images obtained from the diffracted light 397.

To aid the alignment and focusing of the spot S with desired product structures, inspection apparatus 302 may also provide auxiliary optics using auxiliary radiation under control of metrology processor 320. Metrology processor 320 may also communicate with a position controller 372 which operates the translation stage, rotation and/or tilting stages. Processor 320 receives highly accurate feedback on the position and orientation of the substrate, via sensors. Sensors 374 may include interferometers, for example, which may give accuracy in the region of picometers. In the operation of the inspection apparatus 302, spectrum data 382 captured by detection system 318 is delivered to metrology processing unit 320.

As mentioned, an alternative form of inspection apparatus uses hard X-ray, soft X-ray and/or EUV radiation optionally at normal incidence or near-normal incidence, for example to perform diffraction-based measurements of asymmetry. Another alternative form of inspection apparatus uses hard X-ray, soft X-ray and/or EUV radiation with direction being greater than 1° or 2° from a direction parallel to the substrate. Both types of inspection apparatus could be provided in a hybrid metrology system. Performance parameters to be measured may include overlay (OVL), critical dimension (CD), focus of the lithography apparatus while the lithography apparatus printed the target structure, coherent diffraction imaging (CDI) and at-resolution overlay (ARO) metrology. The hard X-ray, soft X-ray and/or EUV radiation may for example have wavelengths less than 100 nm, for example using radiation in the range 5-30 nm, optionally in the range from 10 nm to 20 nm. The radiation may be narrowband or broadband in character. The radiation may have discrete peaks in a specific wavelength band or may have a more continuous character.

Like the optical scatterometer used in today's production facilities, the inspection apparatus 302 may be used to measure structures within the resist material treated within the litho cell (After Develop Inspection or ADI), and/or to measure structures after they have been formed in harder material (After Etch Inspection or AEI). For example, substrates may be inspected using the inspection apparatus 302 after they have been processed by a developing apparatus, etching apparatus, annealing apparatus and/or other apparatus.

Metrology tools MT, including but not limited to the scatterometers mentioned above, may use radiation from a radiation source to perform a measurement. The radiation used by a metrology tool MT may be electromagnetic radiation. The radiation may be optical radiation, for example radiation in the infrared, visible, and/or ultraviolet parts of the electromagnetic spectrum. Metrology tools MT may use radiation to measure or inspect properties and aspects of a substrate, for example a lithographically exposed pattern on a semiconductor substrate. The type and quality of the measurement may depend on several properties of the radiation used by the metrology tool MT. For example, the resolution of an electromagnetic measurement may depend on the wavelength of the radiation, with smaller wavelengths able to measure smaller features, e.g. due to the diffraction limit. In order to measure features with small dimensions, it may be preferable to use radiation with a short wavelength, for example EUV, hard X-ray (HXR) and/or Soft X-Ray (SXR) radiation, to perform measurements. In order to perform metrology at a particular wavelength or wavelength range, the metrology tool MT requires access to a source providing radiation at that/those wavelength(s). Different types of sources exist for providing different wavelengths of radiation. Depending on the wavelength(s) provided by a source, different types of radiation generation methods may be used. For extreme ultraviolet (EUV) radiation (e.g. 1 nm to 100 nm), and/or soft X-ray (SXR) radiation (e.g. 0.1 nm to 20 nm, 1 nm to 20 nm or 10 nm to 20 nm), a source may use High Harmonic Generation (HHG) or any other types of sources mentioned above to obtain radiation at the desired wavelength(s).

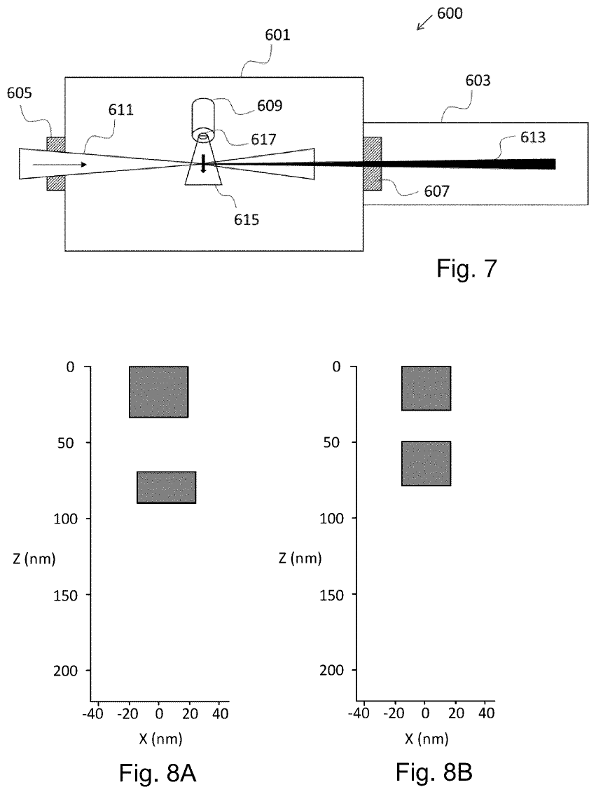

FIG. 7 shows a simplified schematic drawing of an embodiment 600 of an illumination source 310, which may be the illumination source for high harmonic generation (HHG). One or more of the features of the illumination source in the metrology tool described with respect to FIG. 6 may also be present in the illumination source 600 as appropriate. The illumination source 600 comprises a chamber 601 and is configured to receive a pump radiation 611 with a propagation direction which is indicated by an arrow. The pump radiation 611 shown here is an example of the pump radiation 340 from the pump radiation source 330, as shown in FIG. 6. The pump radiation 611 may be directed into the chamber 601 through the radiation input 605, which maybe a viewport, optionally made of fused silica or a comparable material. The pump radiation 611 may have a Gaussian or hollow, for example annular, transversal cross-sectional profile and may be incident, optionally focused, on a gas flow 615, which has a flow direction indicated by a second arrow, within the chamber 601. The gas flow 615 comprises a small volume called gas volume or gas target (for example several cubic mm) of a particular gas (for example, air, Neon (Ne), Helium (He), Nitrogen (N₂), Oxygen (O₂), Argon (Ar), Krypton (Kr), Xenon (Xe), Carbon dioxide and the combination of them.) in which the gas pressure is above a certain value. The gas flow 615 may be a steady flow. Other media, such as metallic plasmas (e.g. aluminium plasma) may also be used.

The gas delivery system of the illumination source 600 is configured to provide the gas flow 615. The illumination source 600 is configured to provide the pump radiation 611 in the gas flow 615 to drive the generation of emitted radiation 613. The region where at least a majority of the emitted radiation 613 is generated is called an interaction region. The interaction region may vary from several tens of micrometers (for tightly focused pump radiation) to several mm or cm (for moderately focused pump radiation) or even up to a few meters (for extremely loosely focused pump radiation). The gas delivery system is configured to provide the gas target for generating the emitted radiation at the interaction region of the gas target, and optionally the illumination source is configured to receive the pump radiation and to provide the pump radiation at the interactive region. Optionally, the gas flow 615 is provided by the gas delivery system into an evacuated or nearly evacuated space. The gas delivery system may comprise a gas nozzle 609, as shown in FIG. 6, which comprises an opening 617 in an exit plane of the gas nozzle 609. The gas flow 615 is provided from the opening 617. The gas catcher is for confining the gas flow 615 in a certain volume by extracting residual gas flow and maintaining a vacuum or near vacuum atmosphere inside the chamber 601. Optionally the gas nozzle 609 may be made of thick-walled tube and/or high thermo-conductivity materials to avoid thermo deformation due to the high-power pump radiation 611.

The dimensions of the gas nozzle 609 may conceivably also be used in scaled-up or scaled-down versions ranging from micrometer-sized nozzles to meter-sized nozzles. This wide range of dimensioning comes from the fact that the setup may be scaled such that the intensity of the pump radiation at the gas flow ends up in the particular range which may be beneficial for the emitted radiation, which requires different dimensioning for different pump radiation energies, which may be a pulse laser and pulse energies can vary from tens of microjoules to joules. Optionally, the gas nozzle 609 has a thicker wall to reduce nozzle deformation caused by the thermal expansion effect, which may be detected by e.g. a camera. The gas nozzle with thicker wall may produce a stable gas volume with reduced variation. Optionally, the illumination source comprises a gas catcher which is close to the gas nozzle to maintain the pressure of the chamber 601.

Due to interaction of the pump radiation 611 with the gas atoms of the gas flow 615, the gas flow 615 will convert part of the pump radiation 611 into the emitted radiation 613, which may be an example of the emitted radiation 342 shown in FIG. 6. The central axes of the emitted radiation 613 may be collinear with the central axes of the incident pump radiation 611. The emitted radiation 613 may have a wavelength in X-ray or EUV range, hereafter referred to as SXR radiation, wherein the wavelength is in a range from 0.01 nm to 100 nm, optionally from 0.1 nm to 100 nm, optionally from 1 nm to 100 nm, optionally from 1 nm to 50 nm, optionally from 2 nm to 50 nm, optionally from 2 nm to 20 nm or optionally from 10 nm to 20 nm.

In operation the emitted radiation 613 beam may pass through a radiation output 607 and may be subsequently manipulated and directed by an illumination system 603, which may be an example of the illumination system 312 in FIG. 6, to a substrate to be inspected for metrology measurements. The emitted radiation 613 may be guided, optionally focused, to a structure on the substrate.

Because air (and in fact any gas) heavily absorbs SXR or EUV radiation, the volume between the gas flow 615 and the wafer to be inspected may be evacuated or nearly evacuated. Since the central axes of the emitted radiation 613 may be collinear with the central axes of the incident pump radiation 611, the pump radiation 611 may need to be blocked to prevent it passing through the radiation output 607 and entering the illumination system 603. This may be done by incorporating a filtering device 344 shown in FIG. 6 into the radiation output 607, which is placed in the emitted beam path and that is opaque or nearly opaque to the pump radiation (e.g. opaque or nearly opaque to infrared or visible light) but at least partially transparent to the emitted radiation beam. The filter may be manufactured using zirconium or multiple materials combined in multiple layers. The filter may be a hollow, optionally an annular, block when the pump radiation 611 has a hollow, optionally an annular, transversal cross-sectional profile. Optionally, the filter is non-perpendicular and non-parallel to propagation direction of the emitted radiation beam to have efficient pump radiation filtering. Optionally, the filtering device 344 comprise a hollow block and a thin membrane filter such as an Aluminum (Al) or Zirconium (Zr) membrane filter. Optionally, the filtering device 344 may also comprise mirrors that efficiently reflect the emitted radiation but poorly reflect the pump radiation, or comprise a wire mesh that efficiently transmits the emitted radiation but poorly transmits the pump radiation.

Described herein are methods, apparatuses, and assemblies to obtain emitted radiation optionally at a high harmonic frequency of pump radiation. The radiation generated through the process, optionally the HHG which uses non-linear effects to generate radiation optionally at a harmonic frequency of provided pump radiation, may be provided as radiation in metrology tools MT for inspection and/or measurement of substrates. If the pump radiation comprises short pulses (i.e. few-cycle) then the generated radiation is not necessarily exactly at harmonics of the pump radiation frequency. The substrates may be lithographically patterned substrates. The radiation obtained through the process may also be provided in a lithographic apparatus LA, and/or a lithographic cell LC. The pump radiation may be pulsed radiation, which may provide high peak intensities for short bursts of time.

The pump radiation 611 may comprise radiation with one or more wavelengths higher than the one or more wavelengths of the emitted radiation. The pump radiation may comprise infrared radiation. The pump radiation may comprise radiation with wavelength(s) in the range of 500 nm to 1500 nm. The pump radiation may comprise radiation with wavelength(s) in the range of 800 nm to 1300 nm. The pump radiation may comprise radiation with wavelength(s) in the range of 900 nm to 1300 nm. The pump radiation may be pulsed radiation. Pulsed pump radiation may comprise pulses with a duration in the femtosecond range.

For some embodiments, the emitted radiation, optionally the high harmonic radiation, may comprise one or more harmonics of the pump radiation wavelength(s). The emitted radiation may comprise wavelengths in the extreme ultraviolet, soft X-Ray, and/or hard X-Ray part of the electromagnetic spectrum. The emitted radiation 613 may comprise wavelengths in one or more of the ranges of less than 1 nm, less than 0.1 nm, less than 0.01 nm, 0.01 nm to 100 nm, 0.1 nm to 100 nm, 0.1 nm to 50 nm, 1 nm to 50 nm and 10 nm to 20 nm.

Radiation, such as high harmonic radiation described above, may be provided as source radiation in a metrology tool MT. The metrology tool MT may use the source radiation to perform measurements on a substrate exposed by a lithographic apparatus. The measurements may be for determining one or more parameters of a structure on the substrate. Using radiation at shorter wavelengths, for example at EUV, SXR and/or HXR wavelengths as comprised in the wavelength ranges described above, may allow for smaller features of a structure to be resolved by the metrology tool, compared to using longer wavelengths (e.g. visible radiation, infrared radiation). Radiation with shorter wavelengths, such as EUVSXR and/or HXR radiation, may also penetrate deeper into a material such as a patterned substrate, meaning that metrology of deeper layers on the substrate is possible. These deeper layers may not be accessible by radiation with longer wavelengths.

In a metrology tool MT, source radiation may be emitted from a radiation source and directed onto a target structure (or other structure) on a substrate. The source radiation may comprise EUV, SXR and/or HXR radiation. The target structure may reflect, transmit and/or diffract the source radiation incident on the target structure. The metrology tool MT may comprise one or more sensors for detecting diffracted radiation. For example, a metrology tool MT may comprise detectors for detecting the positive (+1st) and negative (−1st) first diffraction orders. The metrology tool MT may also measure the specular reflected or transmitted radiation (0th order diffracted radiation). Further sensors for metrology may be present in the metrology tool MT, for example to measure further diffraction orders (e.g. higher diffraction orders).

In an example lithographic metrology application, the HHG generated radiation may be focused onto a target on the substrate using an optical column, which may be referred to as an illuminator, which transfers the radiation from the HHG source to the target. The HHG radiation may then be reflected from the target, detected and processed, for example to measure and/or infer properties of the target.

Gas target HHG configurations may be broadly divided into three separate categories: gas jets, gas cell and gas capillaries. FIG. 7 depicts an example gas jet configuration in which as gas volume is introduced into a drive radiation laser beam. In a gas jet configuration, interaction of the drive radiation with solid parts is kept to a minimum. The gas volume may for example comprise a gas stream perpendicular to the drive radiation beam, with the gas volume enclosed inside a gas cell. In a gas capillary setup, the dimensions of the capillary structure holding the gas are small in a lateral direction such that it significantly influences the propagation of the drive radiation laser beam. The capillary structure may for example be a hollow-core fibre, wherein the hollow core is configured to hold the gas.

A gas jet HHG configuration may offer a relative freedom to shape a spatial profile of the drive radiation beam in the far field, as it is not confined by the restrictions imposed by the gas capillary structure. Gas jet configurations may also have less stringent alignment tolerances. On the other hand, a gas capillary may provide an increased interaction zone of the drive radiation and the gaseous medium, which may optimise the HHG process.

In order to use the HHG radiation, for example in a metrology application, it is separated from the drive radiation downstream of the gas target. The separation of the HHG and drive radiation may be different for the gas jet and gas capillary configurations. In both cases, the drive radiation rejection scheme can comprise a metal transmissive filter for filtering out any remaining drive radiation from the short wavelength radiation. However, before such a filter can be used, the intensity of the drive radiation should be reduced significantly from its intensity at the gas target, in order to avoid damage to the filter. The methods that can be used for this intensity reduction differ for the gas jet and capillary configurations. For a gas jet HHG, due to the relative freedom of the shape and spatial profile (which may also be referred to as a spatial distribution, and/or spatial frequencies) of the drive radiation beam focused onto the gas target, this can be engineered such that in the far field it has a low intensity along the directions where the short wavelength radiation propagates. This spatial separation in the far field means an aperture may be used to block the drive radiation and lower its intensity

In contrast, in a gas capillary structure, the spatial profile of the beam as it passes through the gaseous medium may be largely dictated by the capillary. The spatial profile of the drive radiation may be determined by the shape and material of the capillary structure. For example, in the case of a hollow-core fiber being used as a capillary structure, the shape and materials of the fiber structure determine which modes of drive radiation are supported for propagation through the fiber. For most standard fibres, the supported propagating modes lead to a spatial profile where the high intensity of the drive radiation overlaps with the high intensity of the HHG radiation. For example, the drive radiation intensity may be centred, in a Gaussian or close-to-Gaussian profile in the far field.

In one embodiment of overlay metrology, overlay targets comprise two or more diffraction gratings (sub-structures) printed in different layers such that they overlap. Some of the known overlay metrology methods infer overlay based on measurement of overlay targets with programmed biases (deliberate positional offsets between the sub-structures/gratings). The overlay metrology methods using such biased targets may obviate the need to perform a model-based reconstruction, and therefore reduces the need to know (geometric) stack parameters (also called stack information) between the two or more gratings. The stack information is required for known model-based reconstruction methods. But the stack information is often confidential and therefore not always available.

Some known metrology methods use measurement illumination within the visible wavelength band and biased targets to set up a recipe for overlay metrology. A similar approach may also be used at Soft X-Ray (SXR) wavelengths, where methods based on biased targets to train a model are options for metrology inference, optionally overlay and/or profilometry inference.

The use of targets with multiple biases impacts yield, and such methods remain affected by grating asymmetries, stack imbalances etc. Additionally, some metrology targets are printed in scribe lane, limiting accuracy and requiring additional steps to infer the overlay for product structures. Other metrology methods addresses this latter issue, but this is at the cost of increased complexity in inferring overlay from structures having product-scale pitch. In addition, some metrology methods require a maximum layer separation between the gratings of about 50 nm, which further limits their applicability. One or more of the above mentioned problems may be solved by embodiments of this invention.

In addition to overlay, the reconstruction of critical dimension (CD) and other geometric parameters of printed structures is becoming increasingly important for control of lithographic scanners. Note that CD is a dimension of a structure, and in one embodiment the structure is a space where materials have been removed e.g. etched away by an etch process.

Photoresist profile control can be achieved using scanning electron microscopy (SEM) or transmission electron microscopy (TEM), but such techniques are slow and may be destructive to the structure being measured. As printed structures become more complex (e.g., Gate-all-around, nanosheets, forksheets) it is becoming increasingly desirable to perform such geometric parameter metrology while not requiring information on the actual stack in the target or device (which is typically unavailable). Embodiments of this invention provide fast and non-destructive method for geometric parameter measurements, especially for the complex structures.

It is therefore proposed to perform an N-dimensional reconstruction based metrology method by breaking down the N-dimensional reconstruction (or optimization) problem to a sequence of M (optionally with M<N, optionally with M>N, optionally with M=N) reconstruction (or optimization) problems, each of lower dimensionality L_{M}. Optionally Σ_{M}L_{M}≥N. This simplifies the optimization problem behind the reconstruction procedure and also relaxes the constraints on the prior knowledge on the target required to start the reconstruction. As will be explained in more detail, this is only possible because of particular properties inherent in electromagnetic scattering at SXR wavelengths, especially for wavelength from 2 nm to 50 nm, optionally from 2 nm to 20 nm. Additionally, breaking down the reconstruction has an advantage in the total calculation time of the reconstruction because solving a complex structure at once using an optimizer provides an unfeasible problem in terms of calculation time.

In one embodiment, it is proposed to perform such metrology in at least two main optimization steps. During the first optimization step(s), at least one vertical (or first direction) positional parameter, e.g. a layer thickness related parameter or an effective layer thickness related parameter taking optical properties of the layer into account, is determined or optimized with other parameters being fixed at an estimated value. Note that the determining process in this context may be an optimizing process, i.e. the determined value after a certain step or steps, optionally optimization step or steps, may still be different from an actual value (which is the ground truth), but it is closer to the actual value compared with the values before the certain step or steps. The estimated value may have a difference from actual value. The difference may be up to 10-20% off the actual value. In one embodiment, the estimated values of CDs may be up to 5 nm and 8 nm off the actual values of CDs 40 nm and 50 nm respectively. Vertical (or the first direction) in this context describes the direction perpendicular to the substrate plane, hereafter labelled the Z-direction. This step can be accomplished with high accuracy with limited prior knowledge on the target/structure. With the at least one vertical positional parameter optimized, a one or more second optimization steps can be used to optimize one or more further/other parameters e.g. geometric parameters of interest (e.g., a positional parameter in at least one direction perpendicular to the vertical direction, e.g., one or both directions of the substrate plane (X direction and/or Y direction). The one or more other parameters being determined in the one or more second optimization steps comprise one or more substrate plane positional parameters of the model parameters. The one or more substrate plane positional parameters relate to one or both directions of the substrate plane. The at least one vertical parameter may describe at least one position and/or thickness of a layer or structure. One or both of the first step and second step may comprise multiple sub-steps to individually optimize individual parameters or different subsets of parameters in the Z direction and the X and/or Y directions respectively. In one embodiment, the vertical positional parameter comprises optical properties of the materials, which impact effective optical path in the vertical direction. In one embodiment, the one or more further parameters of interest comprise one or more of a side wall angle, hole or via angle, tilt angle, a floor tilt or other tilt.

As such, the method may comprise determining (and/or optimizing) at least one parameter of interest relating to a structure formed in at least one respective layer on a substrate. The method comprises obtaining measured metrology data relating to a measurement of the structure. The method further comprises obtaining a model, the model describing the structure in terms of a plurality of model parameters. The model parameters comprise estimated values. The method further comprises performing (optionally in sequence) a plurality of optimization steps, based on the measured metrology data, to determine (and/or optimize) the plurality of model parameters. Optionally each of the plurality of optimization steps determines a subset of the plurality of model parameters.

In one embodiment, the step of performing in sequence a plurality of optimization steps comprises performing one or more first optimization steps using the measured metrology data to determine one or more vertical positional parameters of the model parameters. Optionally the step of performing in sequence a plurality of optimization steps further comprises performing one or more second optimization steps subsequently to performance of the one or more first optimization steps, using the measured metrology data and the model with the one or more vertical positional parameters as determined in the one or more first optimization steps, to determine one or more other model parameters of the plurality of model parameters. Optionally the one or more other model parameters are different than the one or more vertical positional parameters. The one or more first optimization steps may optimize the at least one vertical positional parameter (e.g., optimizing only the at least one vertical positional parameter, such that the other model parameters except the at least one vertical positional parameter are fixed during this step); The one or more second optimization steps may optimize at least one other parameter of the model parameters such as, for example, a substrate plane positional parameter of the model parameters (the at least one substrate plane positional parameter relating to one or both directions of the substrate plane). Optionally the optimization sequence may be determined in an initial optimization sequence determination step, e.g., based on the computation of the covariance and correlation matrices of the model parameters.

The methods described herein may use a simulation model such as a forward model to simulate both an electromagnetic interaction between incident field and target/structure and a sensor configuration (e.g., based on a physical sensor configuration or optical configuration used to capture the scattered radiation from the measured structure or target). The forward model may, for example, be based on the Born approximation. Optionally the simulation model is the model which describes the structure in terms of a plurality of model parameters. Optionally the simulation model is part of the model which describes the structure in terms of a plurality of model parameters. Optionally the simulation model is different from the model which describes the structure in terms of a plurality of model parameters.

The method may comprise comparing the measured sensor output (e.g., a diffraction pattern) and the forward model output (modelled diffraction pattern) for different model parameter values till the two outputs are matched (e.g., according to a matching metric). As such, an optimization scheme can be used which varies one or more parameters of the model until the extremum of an appropriate cost function or merit function is found. One example of such a merit function is the cross-correlation of the calculated signal and measured signal (e.g., where the signals may be diffraction intensity of at least one diffraction order). More details of the forward model will be described later.

Soft X-ray (SXR) metrology uses simultaneous multi-wavelength measurement illumination below 100 nm, below 70 nm, below 50 nm, below 30 nm or below 20 nm, e.g., in the range between 10 nm to 20 nm (or any of the ranges disclosed herein elsewhere). This inherently offers higher spatial resolution compared to visible light. At such SXR wavelengths (e.g., at least below 100 nm, especially for wavelength from 2 nm to 50 nm, optionally from 2 nm to 20 nm), most materials have a refractive index close to that of vacuum. That makes the impact of multiple scattering effects, although still present, less prominent than at visible wavelengths. This allows breaking down of parameter inference problem into a set of simplified and independent sub-problems. Hence, although the approach described is a model-based overlay retrieval, it deals with a quasi model-based reconstruction because the requirements on the model are very relaxed. Essentially the only prior knowledge required is very basic knowledge on the type of structure being measured (e.g., in the first example below, the only initial knowledge requirement is that an overlay target is being measured, comprising gratings in two or more patterned layers). Actual values of other geometric and physical parameters of the stack (CDs, permittivities) can be ignored as they will not significantly impact the accuracy on the determination of Z-interfaces (positions of the patterned layer interfaces, comprising the overlay target, in the Z-direction). In other words, the actual position of the interfaces of the patterned layers dominates the measured signal at SXR wavelengths such that those interfaces can be optimized or determined through a very simple representation of the stack, with all other parameters initially set to estimated values (or nominal values) that can be far (e.g. 0%-20% optionally 0%-10%) from the actual values.

At SXR wavelengths and contrary to metrology in the visible spectrum, the parameter space can be thought as factorized in sub-spaces (e.g., Z-interfaces sub-space, overlay sub-space, CDs sub-space etc.) which can be seen as mutually independent from each other. The direct consequence of this is that an optimum can be found for each sub-space sequentially. This leads to a great simplification of the optimization process. In fact, instead of having to optimize all parameters simultaneously (namely to search a maximum in an N-dimensional optimization problem), the problem can be split into a series of lower-dimensional problems which can each be solved in a step-wise approach (sequentially). In a further embodiment, each of the series of lower-dimensional problems may be solved in parallel.

The concepts disclosed will be first described in the context of overlay inference. Methods for inferring other geometrical parameters will then be described using the same basic concept. The method according to an overlay embodiment will be described with reference to FIGS. 8 to 10.

In one embodiment, because an overlay target comprises two patterned layers (which are the two layers containing the diffraction gratings, with the other layers not being patterned) it is proposed to retrieve overlay via two main sequential steps, a first step to optimize the position of the Z-interfaces of the patterned layers in the stack; i.e., the positions of the layer interfaces of the patterned layers within the stack in the direction perpendicular to the substrate plane and a second step to determine or optimize the overlay.

Determining the patterned layer Z-interfaces may comprise using the forward model to find a global extremum or maximum similarity by varying the locations of the sought layer interfaces in the Z-direction, maintain all else fixed (e.g., all other modelled target parameters being maintained at the estimate values). These interfaces may be parametrized by three undefined Z-positions, i.e., an undefined interface positions comprising the bottom Z-interface of the top grating and the top and bottom Z-interfaces of the bottom grating. The top Z-interface of the top grating may be located at Z=0 by definition, such that the other three interfaces are determined relative to this topmost interface. Of course, while this simplifies this step, the method may actively find all four Z-interfaces (e.g., should another interface be taken as reference). The Z-interfaces may be found, for example, by either employing an exhaustive search or through a local or global optimizer, depending on how much prior information is available on the target. If such prior knowledge is limited, then a global optimizer may be preferred. The exhaustive search is a brute force approach that sweeps the value of the interfaces in the forward model within given plausible ranges until it finds the best match between simulated and measured diffraction patterns.

FIG. 8 illustrates an initial position at the beginning of the overlay determination. FIG. 8(a) shows the ground truth (actual target geometry, overlay and CD) and FIG. 8(b) illustrates a first estimate with estimated values. It can be appreciated that the initial estimate is not accurate, and all parameters are significantly out (i.e., CDs, overlay and Z-interfaces). More specifically, in this illustrative example, the true CD values are 38 nm for both top and bottom gratings, in contrast to estimated values of 32 nm. True overlay (offset between the two gratings) is 5 nm in contrast to 0 nm in the estimated target. The target is 1D periodic along the x direction, with a pitch of 90 nm. Only one period is shown in FIG. 8.

It is assumed that there are two patterned layers (1D periodic along the x direction) forming an overlay target. The first step may comprise sweeping over a large range of values for each of the three interfaces of the estimated target (bottom interface of the top grating and top and bottom interface of the bottom grating). For each combination of these interfaces, a simulated far-field signal is generated using the forward model which is then compared to the true signal. This may be the exhaustive search, that is computationally expensive (it sweeps on a 3D space). However, using a Born approximation for example, it is an operation that can still be done in a short time (e.g., less than a minute using present common hardware). For a rigorous solver faster methods can be used.

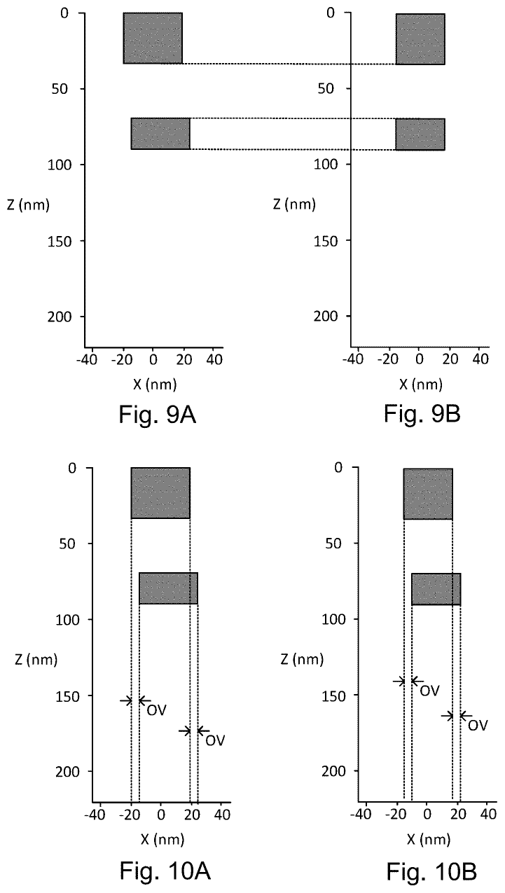

FIG. 9(b) illustrates the situation after the first step has determined the Z-interfaces of the patterned layers, while FIG. 9(a) again shows the ground truth for comparison and is therefore the same as FIG. 8(a). The forward model is used to optimize these Z-interfaces, with all other parameters (including CDs and overlay) being fixed during this optimization. As can be seen from FIG. 9(b), the positions in the stack of the Z-interfaces are accurately retrieved. The CDs and overlay are of course unchanged from the initial estimated values having been fixed and, as such, remain inaccurate. Therefore, despite the modelled target having incorrect CD and overlay values, the Z-interfaces are determined at correct positions. This illustrates that the model/target parameters may be treated as independent parameter sub-spaces.

Once the Z-interface values of the patterned layers are determined, overlay may be determined in a second step, by performing a further, separate, optimization using the forward model. In this optimization step, the now known z-interfaces can be fixed at their determined positions. Optionally, all other parameters can also be fixed, such that only overlay is varied during the optimization. Alternatively, the optimization may optimize overlay and one or more other parameters, such as one or both CDs, together.

The overlay optimization may be achieved by laterally shifting, within the forward model, the position of either grating (or both gratings by differing amounts), such that different overlay values (positional offsets been top and bottom gratings) are modelled. Again, the overlay value may be determined by matching the diffraction pattern from the model with the diffraction pattern actually measured over a range of overlay values.

FIG. 10(b) illustrates the situation after this second step has determined overlay OV, while FIG. 10(a) again shows the ground truth for comparison and is therefore the same as FIGS. 8(a) and 9(a). The overlay OV is accurately determined using the methods disclosed, even though the CD values are still not known accurately.

What makes this approach convenient and able to work in practice, is that at SXR wavelengths, the determination of the Z-interfaces of the patterned layers is essentially insensitive to the actual grating shapes (OVL, CDs etc.) and thicknesses of other layers in the stack. This is a consequence of the above-mentioned low impact of multiple scattering effects at SXR wavelengths. More specifically, when the SXR probe beam interacts with the structure or target (e.g., an overlay target), the interaction between light and target consists of several scattering events: every point in the target is excited by the incident field and produces, in turn, a new field that adds up to the original incident field. This new field can also propagate through other parts of the target, which are now exposed not only to the original field, but also to the field having been produced by the previous scattering events within the target. This process can continue so as to form a multiple scattering process where essentially each small domain in the target contributes to the modification of the total field at every other position within the target. The importance of such higher order scattering events depends on the index of refraction of the materials involved, the wavelength of the light and the size of the target. At SXR wavelengths, especially for wavelength from 2 nm to 50 nm, optionally from 2 nm to 20 nm, while they are not negligible, they are less strong than at visible wavelengths. Therefore accurate values of parameters in Z direction, e.g. the thicknesses of the patterned layers, can be found for the thicknesses of the patterned layers regardless of the starting values of the other parameters.

There has been studies where a quantity (Γ) has been identified that allows to monitor the relevance of such higher scattering events (T. A. van der Sijs, O. El Gawhary, H. P. Urbach, Phys. Rev. Research 2, 013308, 2020. incorporated herein by reference). Such a quantity essentially depends on the permittivity contrast of a medium (Δϵ), its size (d), and the wavelength of the light (λ) according to:

$$Γ = \frac{Δϵ π d}{2 λ}$$

When Γ>>1 (strong scattering regime) multiple scattering is very relevant and in fact comparable in contribution to the original input field. When Γ<<1 (weak scattering regime) multiple scattering effects are negligible while for Γ≅1 or slightly larger than 1 then multiple scattering effects are not negligible, but still they represent a secondary correction to the original input field. It can be shown that for the typical sizes of devices of interest (e.g., in ranges from 40 nm to micrometers) scattering at visible wavelengths exhibits values of Γ of the order of 10 or higher (so are essentially always in the strong scattering regime). On the other hand, at SXR wavelengths, e.g. wavelength from 2 nm to 50 nm, optionally from 2 nm to 20 nm, Γ is around 1, or slightly higher (e.g., below 2, below 1.8, below 1.5 or below 1.5, in each case where the lower bound may be 0.1, 0.5, 0.8 or 0.9 or 1). This is a main difference of the scattering processes at SXR wavelengths than at longer wavelengths.

In addition to this, when the target comprises layers having a periodic pattern, then the periodicity of the target in those layers also imposes a periodicity on the final field scattered by the target. Because the scattered field is periodic, when it propagates away from the target and reaches the detector, it is split in discrete parts (diffraction orders) that propagate along different respective directions in space. In an SXR metrology tool, it is possible to detect some of these diffraction orders separately (e.g., such that the +1^{st} order is separated from the −1^{st} and/or the 2^{nd} orders and so on). The combination of multiple scattering and a periodic target leads to the fact that the signal of a specific diffraction order measured on the detector (e.g., a first order) results not only from the layer comprising the periodic structure, but also on other layers of the stack. How strongly these different layers perturb the main signal coming from the periodic layer depends on whether the multiple scattering is really strong (e.g., consisting of visible range wavelength(s)) or just strong (e.g., consisting of SXR range wavelength(s)). When using SXR radiation, especially radiation with wavelength from 2 nm to 50 nm, optionally from 2 nm to 20 nm, the influence of multiple scattering exists, but is not so strong to result in the signals received from different parts of the target becoming too entangled.

When trying to retrieve the height of e.g., a diffraction grating, these considerations make it possible to ignore the impact of inaccuracies on the thickness of unpatterned layers underneath the grating (because unpatterned layers below or above of the patterned layer can only contribute to the creation of the signal in a diffracted order exclusively through multiple scattering). This physical property, in combination with the proper choice of the merit function, as explained later, enables a stepwise reconstruction of the target to be performed, e.g., starting from the height of the patterned layer, because that is the parameter that determines the largest part of the signal measured.

As a consequence of this, when trying to retrieve the height of a diffraction grating (or layer comprising a diffraction grating), it is possible to first ignore the impact of inaccuracies on other parameters such as CDs and/or the thickness of other unpatterned layers. This physical property makes it possible to break down the reconstruction problem as described, e.g., to perform a step-wise reconstruction of height/Z-positions and overlay of the target.

Another, more general, method will be described to reconstruct or determine other parameters of interest of a structure or target according to the concepts disclosed herein. The specific case described in this embodiment is only an example and the method can be extended to other use cases. In this embodiment, a structure or target is assumed to comprise a 1D periodic grating on top of a multi-layered stack. During the first step of the reconstruction, the at least one vertical positional parameter determined is the height of the grating (e.g., the height of one grating feature). This step can be accomplished with high accuracy with limited prior knowledge on the target, stack below and/or stack above. After the height is determined, one or more other parameters may be reconstructed, such as the thickness of the layers beneath the target and/or the grating CDs, depending on the type of target and/or the required accuracy.

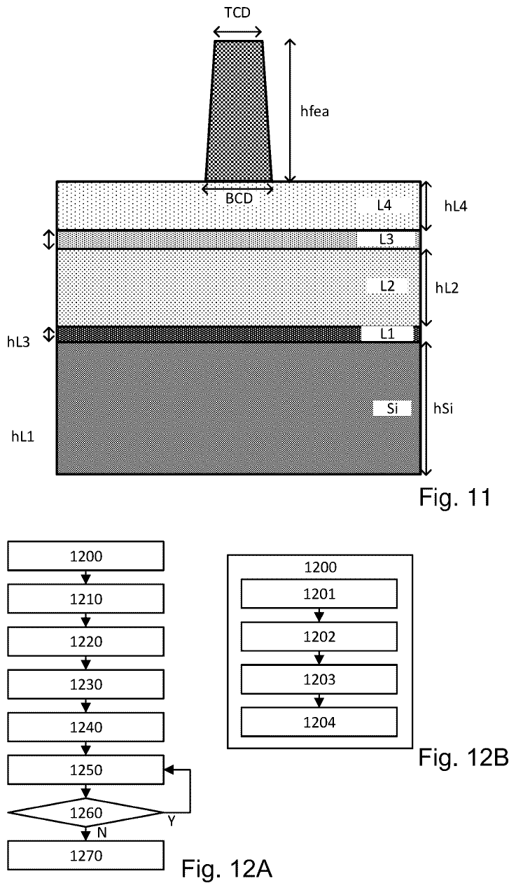

FIG. 11 is a schematic drawing of an example target feature (in resist) on a number of layers. The main parameters of interest describe the shape of the target feature, i.e., the feature height hfea, the top CD TCD and the bottom CD BCD. All other geometries present (e.g., the layer heights hL1-hL4 and silicon height hSi) can also be determined. The method may comprise retrieving the shape of the target feature by first determining the grating height, then (optionally) determining one or more of heights hL1-hL4 of layers L1-L4 (e.g., at least the height hL4 of the top layer L4, which is immediately below the patterned layer). In a further embodiment, the layer L4 is immediately above the patterned layer, where the methods described here are still applicable. This step can then be followed by a step of determining the CDs TCD, BCD of the feature.

As described above, a simulation model or forward model may be used (e.g., based on a rigorous electromagnetic solver). Using the measured sensor output (e.g. a diffraction pattern), an optimization scheme can be set up that varies only the grating's height hfea in the model until the extremum of an appropriate cost function is found. No accurate prior knowledge on the target is required at this stage; all the other geometries labelled in FIG. 11 may be roughly estimated. Since the optimization of this step is for only a single parameter value, an exhaustive search (e.g. a brute force approach that sweeps the value of the height within given plausible ranges until it finds the best match between simulated and measured diffraction patterns) can be used. If there is no prior knowledge available at all, then a global optimizer may be preferred to retrieve the height. Note that the feature height is actually dependent on the positions of the top and bottom of the feature; however the position of the top of the feature may be zero by definition, as in the overlay example.

Once the grating height value hfea is determined, the next parameter to retrieve may be the thickness/height of at least one of the layers (e.g., the topmost layer height hL4). In this example, the height of layer L4 (e.g., a bottom anti-reflective coating BARC) layer may be determined in this step.

Optionally, after performing this step to determine thickness of layer L4 (and/or other layers), the first step may be repeated to improve the reconstruction of the target height hfea, based on the new knowledge of the layer height(s). Because the measured signal is dominated by the target feature parameters, it may be desirable to improve on the target height hfea determination before moving to another parameter.

Once target height is determined, at least one other parameter such as a substrate plane positional parameter can be determined, e.g., such as at least one dimension (e.g., at least one CD) of the structure in one or both directions of the substrate plane. Specifically, in this example, the top CD TCD and bottom CD BCD can then be determined. This is possible only after the height of the grating has been determined with good accuracy. This step may use the forward model as has already been described, with the feature height fixed at the value determined. Additional other parameters may include one or more of any parameters relating to an angle or tilt of the structure or a part thereof, e.g., a side wall angle, hole or via angle, tilt angle, a floor tilt or other tilt.

If desired, optimizations on the thickness of one or more other layers, and/or one or more other parameters can be performed in a further optimization step. In one embodiment, the further optimization step is to determine one or more of the model parameters not determined in the one or more first optimization steps and/or the one or more second optimization steps.

The physical reason that this method enables a good reconstruction of height in an initial step is that the shape of the merit function (which is highly non-linear) is mostly determined by the height value hfea. In other words, the actual position of the interfaces of the patterned layers dominates the measured signal at SXR wavelengths such that those interfaces can be determined through a very simple representation of the stack, with all other parameters initially set to estimated values that can be very far (up to 10% off) from the actual values.

The above embodiments may be generalised into a method for reconstruction or optimization of a complex target (or other structure) comprising the following steps:
a) Determine the height of the patterned layer.
   At this phase the exact values of CDs, layers thicknesses of unpatterned layers can be set to estimated values which do not need to be accurate. The retrieval of the height is a search in a ID space, so can be performed quickly. It may be implemented through an extensive search, a global optimizer that uses a forward solver based on the 1^{st} Born approximation or a global optimizer that uses a rigorous electromagnetic solver.
b) Retrieve the thickness of any anti-reflection coating layers, where present.
c) Retrieve the thickness of other (e.g., thicker) layers.
   At SXR wavelengths, materials do not show a very large difference in refractive index. For example, the largest difference (absolute value) in permittivity between Silicon and resist is 0.07, while the maximum (absolute) value of permittivity of Silicon is 1.034. This means that in the expression of

$$Γ = \frac{Δϵ π d}{2 λ} ,$$

it is the thickness d of a layer that actually determines which parameter (e.g., which layer) contributes the most to multiple scattering corrections to the signal and therefore which is best determined next. As such, it may be that only one or more of the thicker layers (e.g., above a threshold thickness) are determined in this step, and/or this step determines layers in order of thickness (thickest first).
d) Retrieve any other desired parameters e.g., CDs, SWA, corner roundings etc.

Multiple iterations of these steps a) to d) may be performed until a desired accuracy is reached. This can be done in iterations of the full method and/or iterations of subsets of these steps.

Some targets have special features, e.g., so-called pitchwalk targets or overlay targets. Both overlay and pitchwalk impose strong signatures to the measured signal because they break a general symmetry of the system. As such, the method for such targets may include an additional step between steps a) and b) where overlay or pitchwalk (as appropriate) is determined. Of course, as has been described in the terms of overlay targets, it may be that steps c) and d) are then omitted as overlay/pitchwalk are the parameters of interest.

For complex targets, e.g. nanosheets, where within the height of the grating there are substructures, the target can be reconstructed first by ignoring the presence of the substructure and only retrieving the total height of a feature (e.g., fin). After retrieving the height (e.g., step a)) and other layers underneath, a retrieval of the thicknesses and CD of the nanosheets can be performed.

With regard to the optimization steps, these may be based upon using a suitable merit function. It has been observed that, when using a 1st Born approximation to electromagnetic scattering or a rigorous solver (e.g., based on integral equations solving directly the so-called Lippmann-Schwinger equation) at SXR wavelengths, the impact of height change on the measured signal is structurally different to the changes caused by a CD change. A change in height mostly causes a change in the main frequency along with a later shift of the signal observed, with the scale (amplitude) remaining substantially unchanged. By contrast, a change in CD mostly causes a change in scale of the measured signal (amplitude change), causing a negligible change in the main frequency of the signal or its later shift. Because of this observation, a merit function which is only sensitive to the main frequency and lateral shift may be used to retrieve values of the height and not CD. A suitable merit function with this property may be based on a degree of correlation between two signals, e.g., the measured and simulated signals/diffraction patterns; this may be determined as the normalized inner product between the two signals. When CDs are being determined, a different merit function which is sensitive to CD (i.e., sensitive to scale/amplitude) and largely insensitive to height (i.e., low or negligible sensitivity to the main frequency and its shift) may be used.

As such, the merit function for a particular step of the method may be chosen based on the parameter being determined at the particular step of the method. As such, ideally, different merit functions may be chosen for different parameters such that the chosen merit function is only sensitive to the change of the particular parameter being optimized for (at a particular step) and not sensitive to others parameters.

A merit function that is mostly sensitive to shift or frequency change, but not to scaling, would mostly pick height change (z-direction change or vertical positional parameter change). As such, the choice of the merit function can potentially reduce the number of iterations needed by the optimizer to obtain a successful reconstruction.

As such, the merit function used for each optimization in the one or more first optimization steps may comprise a high and/or maximized sensitivity to a main frequency and lateral shift of the measured metrology data and/or simulated metrology data, and a low and/or minimized sensitivity to a scale of the measured metrology data and/or simulated metrology data.

Similarly, the merit function used for each optimization in the one or more second optimization steps may comprise a high and/or maximized sensitivity to a scale of the measured metrology data and/or simulated metrology data, and a low and/or minimized sensitivity to a main frequency and lateral shift of the measured metrology data and/or simulated metrology data.

In an embodiment, one or more of the optimization steps may be regularized, e.g., by adding a regularization term to one or more of the merit functions used. By adding a regularization term to the merit function, the N-dimensional problem may be automatically broken down into multiple sub-problems, sweeping the layers from top to bottom as the iterations increase. The purpose of this regularization is to automate the retrieval strategy described above. For example, a regularization term [symbol] may be defined as:

$$ℛ = {\sum }_{p ∈ P} {c}_{p} ( i ) {‖ {p}_{i} - {p}_{i - 1} ‖}^{2} ,$$

where P is the set of parameters to infer, pᵢ the value of the parameter p at the i-th iteration and where cₚ(i) is a coefficient whose value can be dynamically adjusted at each iteration. For example, one possible way to scale cₚ(i) could be:

$${c}_{p} ( i ) = {α}_{p} ( 1 - {e}^{- \frac{{\vert i - {i}_{p} \vert}^{2}}{{l}_{p}}} ) ,$$

where αₚ, iₚ, lₚ are hyperparameters of the regularization. This specific regularization term penalizes variation of the parameter p outside of a specific window in terms of number of iterations, which allows the optimizer to weakly break down a N-dimension problem as a lower Lₘ-dimension problem, based on the physics of the data formation of an SXR scatterometer without any user input.

This regularization represents a specific case, but any regularization added as a restriction of the parameter space, as a penalizing term or as a physical restriction, on the value of the parameter p is within the scope of this disclosure. Any methods that estimate the hyperparameters of such a regularization, with pre-processing or iterative methods, is also within the scope of this disclosure.

It is proposed to reconstruct a complex geometry by comparing measurements and simulations. In order to do that a rough model of the target (which in the proposed approach, is initially defined and improved at each optimization step of a reconstruction process) and an electromagnetic solver is required. A rigorous electromagnetic solver can be time consuming. On the other hand, models based on a simpler description of the physical interaction between probe and target can be fast, although less accurate.

The forward model has largely been described in terms of approximating the solver based on a Born approximation, where multiple scattering effects are neglected. As explained above, single scattering events mostly contribute to the signal coming from the height of the patterned layer. This means for this height parameter (contributing to the strongest component of the measured signal) the rigorous, and time consuming, Maxwell solver may be replaced by the simpler Born approximation solver. Because the shape of the merit function is expected to be mostly defined by the height of the patterned layer, and that height is mostly encoded in the first scattering event, it can be expected that a good estimate of the height can be obtained using such a simple solver. More generally, the accuracy (and complexity) of the Maxwell solver may be adapted to a current parameter of interest.

As such, any suitable electromagnetic solver (also called rigorous solver) may be used. Electromagnetic solvers differ in the manner they solve Maxwell equations and in the use case they may be suitable for. For example rigorous coupled-wave analysis (RCWA) may be used to solve Maxwell equation for periodic structures and uses an expansion of the field and permittivities in a Fourier series. Other solvers use a numerical approach (e.g., Finite Domain Time Domain FDTD) of finite element methods (FEM) or Modal Methods.

In an embodiment, it is proposed to use of a solver which solves Maxwell equations in their integral form (essentially what is called the vectorial Lipmann-Schwinger equation). However, in principle, which solver is used does not impact the results of the methods disclosed herein; only the speed of the reconstruction and its numerical accuracy and as such, any solver may be used.

Another aspect which may be configured is the optimizer used. Depending on the goal of a particular optimization step, a different choice of optimizer can improve a particular step in terms of speed and/or accuracy. Optimizers can be local or global optimizers. An example of a global optimizer is a Bayesian Optimizer.

A common option is an optimizer based on a Levenberg-Marquardt algorithm. Depending on the step-wise reconstruction strategy, and in particular the goal of a step, the choice of optimizer can improve the reconstruction. For example, if during one of the first reconstruction steps there is uncertainty on the initial estimated values and the interval of certain parameters of interest, the landscape is probably not a convex landscape. With this part of the reconstruction strategy, the landscape is narrowed down to an interval such that it comprises a convex domain. Therefore, a global optimizer, such as e.g., a Bayesian optimizer (see below), may be used to explore the landscape. A global optimization in a confined 1D space is still a relatively fast operation. In a later phase of the reconstruction strategy, when the bounds of the parameters of interest are narrowed down to define a convex problem, a local optimizer may be used to accurately reconstruct the parameters of interest.

As mentioned above, in order to reduce computation time, it is optionally proposed to replace the exhaustive search for the optimum by an adaptive sampling of the merit function based on Bayesian Optimization. An important pre-condition for both approaches to converge, is the existence of a unique global extremum (i.e., no swing curve behaviour) which has been observed to be true in all models when the ranges swept are below the pitch size of the structures. A Bayesian Optimization uses a global optimizer (Bayesian optimizer) to find the global optimum (minimum or maximum) of a merit function. The optimizer may operate in the following way:
1) First the merit function is computed for a few values of the parameter(s) to be retrieved at that step (e.g., initial estimate values). This results in the merit function having a global minimum that is to be found to be sampled at the chosen parameters.
2) The merit function is modelled as a Gaussian Process and the few values measured at step 1) are used to determine the next point in the parameter space where it is most convenient to observe the value of the merit function. This is determined by choosing the value which increases the level of information on the shape of the function.
3) Based on step 2), the merit function is updated with the new value observed; steps 2) and 3) are repeated until a global minimum is found.

In many of the above embodiments, the optimization sequence describing which subset of parameters or subspaces are optimized at each optimization step and in which order, is decided using physical intuition. This means that the method is user-dependent and requires experience of the metrology engineer involved. While generally applicable guidance is described above, e.g., optimizing heights/vertical model parameters first in one or more first optimization steps prior to optimizing other model parameters, the optimal order is not always apparent. For example, for complex geometries it may be difficult to determine an appropriate optimization sequence. Even for relatively simple geometries, better performance may be obtained by optimizing a particular “other model parameter” such as a CD in one of the first optimizations (e.g., in a co-optimization with a vertical model parameter or otherwise) and/or optimizing the vertical model parameters in a particular sequence.

To address this, an optimization sequence determination method is proposed which automatically breaks down the N-dimensional reconstruction problem into the sequence of M reconstruction problems of dimension L_{M}, with Σ_{M}L_{M}≥N.

FIG. 12(a) is a flowchart describing a method of determining an optimization sequence according to an embodiment. This embodiment may determine the optimization sequence based on a computation of covariance and correlation matrices of the model parameters, e.g., based on initial values for these model parameters, and derivatives determined with respect to these model parameters (e.g. in the case of linear approximation).

Step 1200 may comprise determining the covariance and correlation matrices. This step may be broken down into sub-steps as illustrated in FIG. 12(b). At step 1201, the derivatives may be determined, e.g., using the simulation model or forward model as has been described. For example, in order to compute the derivative with respect to a chosen model parameter (“or parameter of interest (POI)”), the signal signal(POI) obtained with a structure defined by the initial values of the model parameters and the signal signal(POI+Δϵ) after the introduction of a small variation Δϵ (e.g., smaller than 100 μm or in the region of 50 pm) of the chosen model parameter is simulated. The derivative J_{POI} with respect to a parameter of interest POI may be obtained using forward numerical differentiation:

$${J}_{POI} = \frac{{Δ}_{Δϵ} signal ( P O I )}{Δϵ} = \frac{signal ( P O I + Δϵ ) - signal ( P O I )}{Δϵ}$$

This is only an example derivative determination method. Another method may comprise determining the finite first derivative as the symmetric finite derivative:

$${J}_{POI} = \frac{{Δ}_{Δϵ} signal ( P O I )}{Δϵ} = \frac{signal ( P O I + Δϵ / 2 ) - signal ( P O - Δϵ / 2 )}{Δϵ}$$

Another alternative may use automatic differentiation in the computational model to calculate the derivative, or any kernel based method: e.g., J=h*signal.

At step 1202, these derivatives may be determined with respect to each model parameter and then stacked in a matrix J (Jacobian), e.g., having dimensions defined by the number of model parameters x number of pixels.

The covariance matrix C_{cov} can then be determined (step 1203), e.g., from:

$${c}_{cov} = {( {J}^{t} {C}_{noise}^{- 1} J )}^{- 1}$$

where matrix

$${C}_{noise}^{- 1}$$

is the inverse of the matrix representing the autocorrelation of the noise in the signal. For uncorrelated noise (e.g., photon shot noise or camera read out noise), the noise per pixel may be defined by a noise model for that specific pixel.

At step 1204, the correlation matrix C_{cor,ij} may be obtained from the covariance matrix by a rescaling, e.g., according to:

$${C}_{cor , ij} = \frac{{C}_{cov , ij}}{\sqrt{{C}_{cov , ii} {C}_{cov , jj}}}$$

Once the correlation matrix and the covariance matrix are computed, they may be used to divide the model parameters into subsets (subspaces), for example by performing steps 1210 to 1280.

Step 1210, may comprise determining measurement repeatability metric data for the model parameters given the noise introduced in the model. For example, this measurement repeatability metric data may be determined from the covariance matrix diagonal elements, as these diagonal elements correspond to measurement repeatability.

At step 1220, each model parameter's repeatability may be scaled using a characteristic quantity for that model parameter. Good candidates for characteristic quantities are: variations due to the manufacturing process and/or a specific target value for the manufacturing process. Both the unscaled repeatability determined at step 1210 and the rescaled repeatability determined in this step are examples of a measurement repeatability metric.

At step 1230, the model parameters may be ordered or ranked in accordance with the rescaled repeatability determined at step 1220 to obtain ranked model parameters. Model parameters with lower rescaled repeatability tend to have lower associated noise and larger variation ranges. These model parameters may tend to be vertical model parameters such as heights of the structure.

At step 1240, a regularization technique may be applied to address model parameters having high rescaled repeatability, as the problem becomes ill-conditioned if the rescaled repeatability is high. Different regularization techniques can mitigate or solve this issue. A proposed regularization technique may comprise excluding all model parameters with high rescaled repeatability. This is a specific example regularization technique (space restriction), but any suitable state-of-the-art regularization technique may be used. An appropriate threshold rescaled repeatability value or threshold repeatability metric value may be used to divide the model parameters into those with high model rescaled repeatability and low rescaled repeatability, for example.

At step 1250, out of the remaining model parameters (e.g., those having a repeatability metric value below the threshold repeatability metric value), the model parameter with lowest associated repeatability metric (e.g., rescaled repeatability) may be selected and the correlation of this selected model parameter with the other model parameters considered, e.g., using the correlation matrix determined at step 1200. Any of the other model parameters having a correlation value or correlation coefficient higher than a correlation threshold C_{threshold} may be grouped together with the selected model parameter. In this way, a first group (i.e., the model parameter with the lowest repeatability metric value and any correlated parameters grouped with it) may be defined and used as the first optimization subset of model parameters (i.e., the first subset of model parameters to be optimized).

At step 1260 it is determined whether there are any more model parameters which have not yet been assigned a group. If there is Y, then the model parameter having the next lowest associated repeatability metric is selected and step 1250 repeated to determine the next optimization subset of model parameters. This is repeated till all the model parameters (e.g., other than those excluded at step 1240) have been grouped.

At step 1270, the structure may be reconstructed according to the optimization sequence determined.

The method described above can be interpreted in a more rigorous way in a Bayesian framework (e.g., as already described) using the prior and posterior distribution. In such an embodiment, the characteristic quantities used in step 1220 can be interpreted as prior uncertainties and the repeatability metric may describe the variance of the likelihood distributions. This formalism allows for a rigorous analytical interpretation of the regularization described in step 1240.

The covariance and correlation matrices may optionally be recomputed for spaces that are more suitable for the reconstruction, e.g., new subspaces can be determined via the diagonalization of the covariance and correlation matrices; these new subspaces may comprise linear combinations of model parameters that are less correlated with each other.

Step 1250 describes a particular algorithm for determining connectivity for a graph. This is only an example method and any suitable method for determining connectivity in matrices may be used, including graph-based methods.

The method described above takes into account only problem model parameters, but other quantities can be added to the problem if they are important for the reconstruction. For example, if one parameter of the sensor model is important for the target reconstruction, but its calibration is not sufficiently accurate, this parameter may be designated a model parameter and included in the procedure, thereby relaxing the specifications on the parameter calibration.

This embodiment handles crosstalk between model parameters using a linear approximation. A possible extension to this may take into account non-linear crosstalk. Non-linear crosstalk can be quantified and used in this method in any suitable manner (e.g., computing the Hessian or sampling the whole parameter space to retrieve the crosstalk between the model parameters).

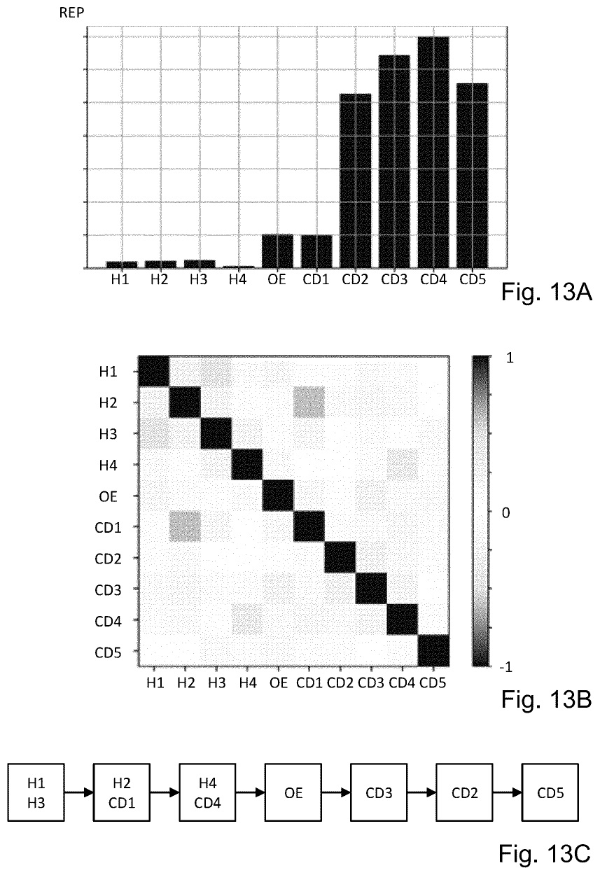

A specific example is described with reference to FIG. 13. A structure may be described by 10 model parameters, comprising 4 vertical model parameters or heights H1, H2, H3, H4, an over etch model parameter OE and 5 CD model parameters CD1, CD2, CD3, CD4, CD5. FIG. 13(a) shows the repeatability values REP for each of these model parameters, e.g., as described by the diagonal of the covariance matrix. FIG. 13(b) shows the correlation matrix for these model parameters. Assuming an exemplary correlation threshold C_{thresnold} of 0.3, then the model parameters may be grouped and sequenced into the optimization sequence shown in FIG. 13(c), wherein each box comprises the one or more model parameters to be optimized at each optimizations step.

Unsurprisingly, the model parameters to be optimized first include the heights. However, this method also informs that parameter CD1 should be optimized early, i.e., in combination with parameter H2, and as such captures the importance of the correlation between these two parameters. It may be that taking into account this correlation is fundamental for the success of the reconstruction, as reconstructing these parameters separately leads to a reconstruction error of the order of the (relatively high) sensitivity of CD1 on H2. Similarly, this method informs that parameter CD4 should be optimized with parameter H4.

An embodiment may include a computer program containing one or more sequences of machine-readable instructions describing a method of optical metrology and/or a method of analysing a measurement to obtain information about a lithographic process. An embodiment may comprise computer code containing one or more sequences of machine-readable instructions or data describing the method. This computer program or code may be executed for example within unit MPU in the apparatus of FIG. 6 and/or the control unit CL of FIG. 3. There may also be provided a data storage medium (e.g., semiconductor memory, magnetic or optical disk, etc.) having such a computer program or code stored therein. Where an existing metrology apparatus, for example of the type shown in FIG. 6, is already in production and/or in use, an embodiment of the invention can be implemented by the provision of an updated computer program product for causing a processor to perform one or more of the methods described herein. The computer program or code may optionally be arranged to control the optical system, substrate support and the like to perform a method of measuring a parameter of the lithographic process on a suitable plurality of targets. The computer program or code can update the lithographic and/or metrology recipe for measurement of further substrates. The computer program or code may be arranged to control (directly or indirectly) the lithographic apparatus for the patterning and processing of further substrates.

The above embodiments have one or more of the following advantages over currently exiting model-based methods, including:
The first step of determining parameters related to Z direction, e.g. stack thicknesses, can be done with high accuracy with limited prior knowledge;
Instead of having to optimize all parameters simultaneously, the problem can be split into a series of lower-dimensional problems that can each be solved independently, which bring great simplification of the optimization process.
It can be implemented directly on device, e.g. it can be implemented on device for OVL measurement.

The illumination source may be provided in for example a metrology apparatus MT, an inspection apparatus, a lithographic apparatus LA, and/or a lithographic cell LC.

The properties of the emitted radiation used to perform a measurement may affect the quality of the obtained measurement. For example, the shape and size of a transverse beam profile (cross-section) of the radiation beam, the intensity of the radiation, the power spectral density of the radiation etc., may affect the measurement performed by the radiation. It is therefore beneficial to have a source providing radiation that has properties resulting in high quality measurements.

Further embodiments are disclosed in the subsequent numbered clauses:
1. A method of determining at least one parameter of interest relating to a structure formed in at least one respective layer on a substrate, the method comprising:
obtaining a measured metrology data relating to a measurement of the structure;
obtaining a model, the model describing the structure in terms of a plurality of model parameters, the model parameters comprising estimated values; and
performing in sequence a plurality of optimization steps, based on the measured metrology data, to determine the plurality of model parameters, each of the plurality of optimization steps determining a subset of the plurality of model parameters.
2. A method according to clause 1, wherein the step of performing in sequence a plurality of optimization steps comprises:
performing one or more first optimization steps using the measured metrology data to determine one or more vertical positional parameters of the model parameters; and performing one or more second optimization steps subsequently to performance of the one or more first optimization steps, using the measured metrology data and the model with the one or more vertical positional parameters as determined in the one or more first optimization steps, to determine one or more other model parameters of the plurality of model parameters, the one or more other model parameters being different than the one or more vertical positional parameters.
3. A method according to clause 2, wherein the step of performing one or more first optimization steps optimizes only the one or more vertical positional parameters.
4. A method according to clause 2 or 3, comprising performing each the one or more first optimization steps with the model parameters fixed, except for the one or more vertical positional parameters being optimized.
5. A method according to any of clauses 2 to 4, wherein the one or more other parameters being determined in the one or more second optimization steps comprise one or more substrate plane positional parameters of the model parameters, the one or more substrate plane positional parameters relating to one or both directions of the substrate plane.
6. A method according to any of clauses 2 to 5, comprising performing each the one or more second optimization steps with the model parameters fixed, except for the one or more other parameters being determined in the one or more second optimization steps and such that the one or more vertical positional parameters are fixed at values determined in the one or more first optimization steps.
7. A method according to any of clauses 2 to 6, wherein each optimization step of the one or more first optimization steps and of the one or more second optimization steps each comprises comparing the measured metrology data to simulated metrology data obtained by a simulation of measurement of the structure as defined by the model.
8. A method according to clause 7, wherein each optimization step comprises maximizing a similarity of the measured metrology data and simulated metrology data.
9. A method according to clause 7 or 8, wherein the simulation uses a simulation model being operable to simulate an electromagnetic interaction between an incident field, the structure as defined by the model and a sensor configuration.
10. A method according to clause 9, wherein the sensor configuration is based on a physical sensor configuration used to obtain the measured metrology data.
11. A method according to clause 9 or 10, wherein the simulation model comprises a forward model.
12 A method according to clause 9, 10 or 11, wherein the simulation model is based upon a Born approximation and/or a rigorous solver.
13. A method according to any of clauses 7 to 12, wherein each optimization step uses a respective merit function.
14. A method according to clause 13, comprising selecting the merit function for each the optimization step based on the model parameter being optimized at that optimization step.
15. A method according to clause 13 or 14, wherein the merit function used for each optimization in the one or more first optimization steps comprises a high and/or maximized sensitivity to a main frequency and lateral shift of the measured metrology data and/or simulated metrology data, and a low and/or minimized sensitivity to a scale of the measured metrology data and/or simulated metrology data.
16. A method according to clause 13, 14 or 15, wherein the merit function used for each optimization in the one or more first optimization steps is based upon a degree of correlation between the measured metrology data and simulated metrology data.
17. A method according to any of clauses 13 to 16 wherein the merit function used for each optimization in the one or more second optimization steps comprises a high and/or maximized sensitivity to a scale of the measured metrology data and/or simulated metrology data, and a low and/or minimized sensitivity to a main frequency and lateral shift of the measured metrology data and/or simulated metrology data.
18. A method according to any of clauses 13 to 17, comprising selecting an optimizer for one or more of the optimization steps depending on a goal of the optimization step.
19. A method according to any of clauses 13 to 18, wherein one or more of the optimization steps use an optimizer based on a Levenberg-Marquardt algorithm.
20. A method according to any of clauses 13 to 19, wherein one or more of the optimization steps comprise an adaptive sampling of the merit function based on Bayesian Optimization.
21. A method according to any of clauses 13 to 20, comprising regularizing one of more of the optimization steps by applying at least one regularization term to one or more of the merit functions.
22. A method according to clause 21, wherein the at least one regularization term penalizes variation of the model parameter being optimized outside of a specific window in terms of number of iterations.
23. A method according to any of clauses 7 to 22, wherein the measured metrology data and the simulated metrology data each comprises diffraction pattern intensity or amplitude data.
24. A method according to any of clauses 2 to 23, wherein:
the structure comprises an overlay target comprising a sub-structure in respective layers of two or more patterned layers;
the one or more vertical positional parameters comprises at least the respective positions of each undefined interface of the two patterned layers; and
the one or more one or more other parameters being determined in the one or more second optimization steps comprise overlay in one or both directions of the substrate plane.
25. A method according to clause 24, wherein the undefined interfaces comprise all interfaces of the two or more patterned layers other than the topmost interface, such that the undefined interfaces are determined relative to the topmost interface.
26. A method according to any of clauses 2 to 23, wherein:
the one or more vertical positional parameters comprises a height of the structure; and
the one or more one or more other parameters being determined in the one or more second optimization steps comprise at least one dimension of the structure in one or both directions of the substrate plane.
27. A method according to clause 26, wherein the one or more one or more other parameters being determined in the one or more second optimization steps comprise at least one critical dimension of a feature of the structure.
28. A method according to clause 26 or 27, wherein the one or more one or more other parameters being determined in the one or more second optimization steps comprise a top critical dimension at the top of the feature and a bottom critical dimension at the bottom of the feature.
29. A method according to clause 26, 27 or 28, wherein the one or more one or more other parameters being determined in the one or more second optimization steps comprise one or more of a side wall angle of any wall of the structure, a measure of a floor tilt of the structure and/or a measure of any other tilt of the structure.
30. A method according to any of clauses 26 to 29, wherein the one or more vertical positional parameters further comprises a height of one or more of the layers below or above the structure.
31. A method according to clause 30, wherein the performing one or more first optimization steps comprises:
determining the height of the structure;
determining the height of one or more of the layers immediately below or above the structure; and
repeating the step of determining the height of the structure using the determined the height of one or more of the layers immediately below or above the structure.
32. A method according to any of clauses 2 to 31, comprising performing one or more further optimization steps to determine one or more of the model parameters not determined in the one or more first optimization steps and/or the one or more second optimization steps.
33. A method according to any preceding clause, comprising an initial step of determining an optimization sequence describing said sequence of the plurality of optimization steps.
34. A method according to clause 33, comprising determining a measurement repeatability metric for each of said model parameters or a subset thereof, in the presence of noise; and determining said optimization sequence from said measurement repeatability metric.
35. A method according to clause 34, comprising:
determining a covariance matrix describing covariance of the model parameters in the presence of noise; and
determining the measurement repeatability metric for each of said model parameters from the diagonal of said covariance matrix.
36. A method according to clause 35, comprising:
determining derivatives with respect to each model parameter; and
determining said covariance matrix from said derivatives.
37. A method according to any of clauses 34 to 36, comprising ranking said model parameters according to the measurement repeatability metric to obtain ranked model parameters.
38. A method according to clause 37 comprising applying a regularization for model parameters having a high measurement repeatability metric.
39. A method according to clause 38, wherein said regularization comprises excluding those model parameters having a high measurement repeatability metric from the ranking.
40. A method according to any of clauses 37 to 39, comprising:
selecting the model parameter having the lowest measurement repeatability metric;
determining a correlation value between the selected model parameter and the other ranked model parameters;
grouping any model parameters having a correlation value above a correlation threshold with the selected model parameter to obtain groups of said model parameters; and
repeating these steps till all ranked model parameters are grouped, said optimization sequence comprising said groups sequenced according to the measurement repeatability metric of the respective selected model parameter of each group.
41. A method according to clause 40, comprising determining a correlation matrix from said covariance matrix.
42. A method according to any preceding clause, wherein the measured metrology data has been obtained using a measurement illumination having a wavelength smaller than 100 nm.
43. A method according to any preceding clause, wherein the measured metrology data has been obtained using measurement illumination having a wavelength smaller than 50 nm.
44. A method according to clause 43, wherein the measured metrology data has been obtained using measurement illumination comprising a wavelength from 2 nm to 50 nm.
45. A method according to any of clauses 1 to 43, wherein the measured metrology data has been obtained using measurement illumination having a wavelength smaller than 20 nm.
46. A method according to any preceding clause, wherein the measured metrology data has been obtained using measurement illumination comprising a wavelength from 2 nm to 20 nm.
47. A method according to any preceding clause, wherein the number of optimization steps of the plurality of optimization steps comprising a smaller number than the number of model parameters of the plurality of model parameters.
48. A method according to any preceding clause, comprising performing a measurement of the structure to obtain the measured metrology data.
49. A computer program comprising program instructions operable to perform the method of any preceding clause, when run on a suitable apparatus.
50. A non-transient computer program carrier comprising the computer program of clause 49.
51. A processing arrangement comprising:
a computer program carrier comprising the computer program of clause 50; and
a processor operable to run the computer program.
52. A metrology device comprising the processing arrangement of clause 51.
53. A metrology device being operable to perform the method according to clause 48.
54. A metrology device according to clause 52 or 53 comprising a scatterometer.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments in the context of a lithographic apparatus, embodiments may be used in other apparatus. Embodiments may form part of a mask inspection apparatus, a metrology apparatus, or any apparatus that measures or processes an object such as a wafer (or other substrate) or mask (or other patterning device). These apparatuses may be generally referred to as lithographic tools. Such a lithographic tool may use vacuum conditions or ambient (non-vacuum) conditions.

Although specific reference may be made in this text to embodiments in the context of an inspection or metrology apparatus, embodiments may be used in other apparatus. Embodiments may form part of a mask inspection apparatus, a lithographic apparatus, or any apparatus that measures or processes an object such as a wafer (or other substrate) or mask (or other patterning device). The term “metrology apparatus” (or “inspection apparatus”) may also refer to an inspection apparatus or an inspection system (or a metrology apparatus or a metrology system). E.g. the inspection apparatus that comprises an embodiment may be used to detect defects of a substrate or defects of structures on a substrate. In such an embodiment, a characteristic of interest of the structure on the substrate may relate to defects in the structure, the absence of a specific part of the structure, or the presence of an unwanted structure on the substrate.

Although specific reference may have been made above to the use of embodiments in the context of optical lithography, it will be appreciated that the invention, where the context allows, is not limited to optical lithography and may be used in other applications, for example imprint lithography.

While the targets or target structures (more generally structures on a substrate) described above are metrology target structures specifically designed and formed for the purposes of measurement, in other embodiments, properties of interest may be measured on one or more structures which are functional parts of devices formed on the substrate. Many devices have regular, grating-like structures. The terms structure, target grating and target structure as used herein do not require that the structure has been provided specifically for the measurement being performed. Further, pitch of the metrology targets may be close to the resolution limit of the optical system of the scatterometer or may be smaller, but may be much larger than the dimension of typical non-target structures optionally product structures made by lithographic process in the target portions C. In practice the lines and/or spaces of the overlay gratings within the target structures may be made to include smaller structures similar in dimension to the non-target structures.

While specific embodiments have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of interest of the structure on the substrate may relate to defects in the structure, the absence of a specific part of the structure, or the presence of an unwanted structure on the substrate or on the wafer.

Although specific reference is made to SXR electromagnetic radiations, it will be appreciated that the invention, where the context allows, may be practiced with all electromagnetic radiations, includes radio waves, microwaves, infrared, (visible) light, ultraviolet, EUV, HXR, and gamma rays.

While specific embodiments have been described above, it will be appreciated that one or more of the features in one embodiment may also be present in a different embodiment and that features in two or more different embodiments may also be combined.

1-15. (canceled)

16. A method of determining at least one parameter of interest relating to a structure formed in at least one respective layer on a substrate, the method comprising:
obtaining a measured metrology data relating to a measurement of the structure;
obtaining a model, the model describing the structure in terms of model parameters, the model parameters comprising estimated values; and
performing in sequence a plurality of optimizations based on the measured metrology data to determine the model parameters, each of the plurality of optimizations determining a subset of the model parameters.

17. The method of claim 16, wherein the performing comprises:
performing one or more first optimization steps using the measured metrology data to determine one or more vertical positional parameters of the model parameters; and
performing one or more second optimization steps subsequently to performance of the one or more first optimization steps, using the measured metrology data and the model with the one or more vertical positional parameters as determined in the one or more first optimization steps, to determine one or more other model parameters of the plurality of model parameters, the one or more other model parameters being different than the one or more vertical positional parameters.

18. The method of claim 17, comprising performing each the one or more first optimization steps with the model parameters fixed, except for the one or more vertical positional parameters being optimized.

19. The method of claim 17, wherein the one or more other parameters being determined in the one or more second optimization steps comprise one or more substrate plane positional parameters of the model parameters, the one or more substrate plane positional parameters relating to one or both directions of the substrate plane.

20. The method of claim 17, comprising performing each the one or more second optimization steps with the model parameters fixed, except for the one or more other parameters being determined in the one or more second optimization steps.

21. The method of claim 17, wherein each optimization step of the one or more first optimization steps and of the one or more second optimization steps each comprises comparing the measured metrology data to simulated metrology data obtained by a simulation of measurement of the structure as defined by the model.

22. The method of claim 21, wherein:
the simulation uses a simulation model being operable to simulate an electromagnetic interaction between an incident field, the structure as defined by the model and a sensor configuration, and
the sensor configuration is based on a physical sensor configuration used to obtain the measured metrology data.

23. The method of claim 22, wherein the simulation model comprises a forward model.

24. The method of claim 22, wherein the simulation model is based upon a Born approximation and/or a rigorous solver.

25. The method of claim 17, wherein:
the one or more vertical positional parameters comprises a height of the structure; and
the one or more one or more other parameters being determined in the one or more second optimization steps comprise at least one dimension of the structure in one or both directions of the substrate plane.

26. The method of claim 17, comprising performing one or more further optimization steps to determine one or more of the model parameters not determined in the one or more first optimization steps and/or the one or more second optimization steps.

27. The method of claim 16, wherein the measured metrology data is obtained using a measurement illumination comprising illumination with wavelength from about 2 nm to about 50 nm or from about 2 nm to about 20 nm.

28. The method of claim 16, wherein a number of optimizations of the optimizations comprising a smaller number than the number of model parameters of the plurality of model parameters.

29. A computer program comprising program instructions operable to perform the method of claim 16, when run on a suitable apparatus.

30. A metrology device being operable to perform the method of claim 16.
